(19) United States
(12) Patent Application Publication
(10) Pub. No.: US 2013/0107463 A1
(43) Pub. Date: May 2, 2013

(54) ELECTRONIC DEVICE AND DISPLAY DEVICE

(71) Applicant: Tatsuro Kuroda, Osaka-shi (JP)

(72) Inventor: Tatsuro Kuroda, Osaka-shi (JP)

(73) Assignee: SHARP KABUSHIKI KAISHA, Osaka-shi, Osaka (JP)

(21) Appl. No.: 13/808,293

(22) PCT Filed: Apr. 28, 2011
(86) PCT No.: PCT/JP2011/060388

§ 371 Date: Jan. 4, 2013

(30) Foreign Application Priority Data
Jul. 14, 2010 (JP) 2010-159935

(51) Int. Cl. H05K 7/20

(52) U.S. Cl. CPC H05K 7/2039
USPC 361/719

(57) ABSTRACT

An electronic device includes: a semiconductor package; a substrate having an attachment surface to which the semiconductor package is attached; a chassis which is arranged opposite a surface on the opposite side to the attachment surface of the substrate and in which ribs protruding to the side of the substrate are provided; and a heat dissipation sheet which is arranged between the ribs of the chassis and the substrate.

### TECHNICAL FIELD

The present invention relates to electronic devices and display devices, and more particularly relates to an electronic device and a display device that include a substrate to which a semiconductor package is attached.

### BACKGROUND ART

Conventionally, there are known electronic devices that include a substrate to which a semiconductor package is attached. FIG. 40 is a cross-sectional view showing the structure of an example of a conventional electronic device that includes a substrate to which a semiconductor package is attached.

The electronic device 5001 of the conventional example includes, as shown in FIG. 40, a plurality of semiconductor packages 5002, a substrate 5003 to which the semiconductor packages 5002 are attached, heat dissipation sheets 5004 that are arranged on the semiconductor packages 5002, a metal plate 5005 that is in contact with the semiconductor packages 5002 through the heat dissipation sheets 5004 and a chassis 5006 that is arranged a predetermined distance away from the substrate 5003.

The semiconductor packages 5002 include semiconductor packages 5002a and 5002b having a different thickness. For example, the semiconductor package 5002b has a larger thickness than the semiconductor package 5002a.

The heat dissipation sheets 5004 includes a heat dissipation sheet 5004a that is arranged on the semiconductor package 5002a and a heat dissipation sheet 5004b that is arranged on the semiconductor package 5002b. For example, the heat dissipation sheet 5004b has a smaller thickness than the heat dissipation sheet 5004a.

The semiconductor package 5002a is in contact with the metal plate 5005 through the heat dissipation sheet 5004a; the semiconductor package 5002b is in contact with the metal plate 5005 through the heat dissipation sheet 5004b. Thus, it is possible to dissipate heat generated in the semiconductor packages 5002 to the metal plate 5005.

The substrate 5003 and the metal plate 5005 are fixed to the chassis 5006 with an unillustrated fixing member.

A structure in which heat generated in a semiconductor package is dissipated to a metal plate is disclosed in, for example, patent document 1 and patent document 2.

### RELATED ART DOCUMENT

### Patent Document

Patent document 1: JP-A-10-308484
Patent document 2: JP-A-2010-2745 (paragraph [0056])

### DISCLOSURE OF THE INVENTION

### Problems to be Solved by the Invention

However, in the electronic device 5001 of the conventional example, variations in manufacturing or the like may prevent the metal plate 5005 from being in contact with the semiconductor packages 5002 (heat dissipation sheets 5004).

For example, as shown in FIG. 41, when variations in manufacturing cause the attachment height (distance from the attachment surface of the substrate 5003 to the upper surface of the semiconductor package 5002a) of the semiconductor package 5002a to become less than a design value, the metal plate 5005 may not be in contact with the semiconductor package 5002a (the heat dissipation sheet 5004a). Hence, it is disadvantageously difficult to dissipate the heat generated in the semiconductor package 5002a to the metal plate 5005.

The present invention is made to solve the above problem; an object of the present invention is to provide an electronic device and a display device that can reduce the decrease in heat dissipation.

### Means for Solving the Problem

To achieve the above object, according to a first aspect of the present invention, there is provided an electronic device including: a semiconductor package; a substrate having an attachment surface to which the semiconductor package is attached; a first metal plate which is arranged opposite a surface on an opposite side to the attachment surface of the substrate and in which a first protrusion portion protruding to a side of the substrate is provided; and a first heat conductive member which is arranged between the first protrusion portion of the first metal plate and the substrate.

In the electronic device of the first aspect, as described above, the first metal plate which is arranged opposite the surface on the opposite side to the attachment surface of the substrate and the first heat conductive member which is arranged between the first protrusion portion of the first metal plate and the substrate are provided, and thus it is possible to dissipate heat generated in the semiconductor package to the first metal plate through the substrate and the first heat conductive member.

In the electronic device of the first aspect, even if variations in manufacturing cause the attachment height (a distance from the attachment surface of the substrate to the external surface (for example, the upper surface) of the semiconductor package) of the semiconductor packages to become less than a design value, since the distance from the first protrusion portion to the substrate is not changed, it is possible to prevent the first protrusion portion from being brought out of contact with the substrate (the first heat conductive member). Thus, it is possible to reduce the decrease in the heat dissipation of the electronic device.

In the electronic device of the first aspect, as described above, in the first metal plate, the first protrusion portion protruding to the side of the substrate is provided, and thus it is also possible to reduce the thickness of the first heat conductive member. In this way, it is possible to enhance the heat dissipation of the electronic device and reduce the cost of the first heat conductive member.

In the electronic device of the first aspect, since the heat generated in the semiconductor package can be dissipated to the side of the back surface (surface on the opposite side of the attachment surface) of the substrate, unlike the case where the heat generated in the semiconductor package is dissipated to the side of the attachment surface of the substrate, it is not necessary to provide a heat dissipation member or the like on the side of the attachment surface of the substrate. This, it is also possible to reduce the increase in the side of the electronic device as a whole.

Preferably, in the electronic device of the first aspect, the first protrusion portion includes a contact portion which is in contact with the substrate through the first heat conductive member and a spring portion which applies a force acting toward the side of the substrate to the contact portion. In this configuration, since the spring portion can apply a force acting toward the side of the substrate to the contact portion, it is possible to more reliably bring the contact portion into contact with the substrate (the first heat conductive member).

Preferably, in the electronic device where the first protrusion portion includes the contact portion and the spring portion, the first protrusion portion is formed by bending the first metal plate. In this configuration, it is possible to easily form, in the first metal plate, the first protrusion portion protruding to the side of the substrate and easily form the spring portion that applies a force acting toward the side of the substrate to the contact portion.

Preferably, in the electronic device where the first protrusion portion includes the contact portion and the spring portion, a cut portion is formed around the first protrusion portion of the first metal plate. In this configuration, the first metal plate is bent, and thus it is possible to easily form the first protrusion portion. It is also possible to form the first protrusion portion in a desired portion of the first metal plate.

Preferably, in the electronic device where the cut portion is formed around the first protrusion portion of the first metal plate, in the first metal plate, a second heat conductive member is provided which is placed across the cut portion and which is in contact with the first protrusion portion and a portion of the first metal plate other than the first protrusion portion. Although, in the case where the cut portion is formed around the first protrusion portion, the heat generated from the semiconductor package (the first heat conductive member) is transmitted (dissipated) in the direction in which the cut portion is not formed, as described above, the second heat conductive member is provided which is placed across the cut portion and which is in contact with the first protrusion portion and the portion of the first metal plate other than the first protrusion portion, and thus it is possible to transmit (dissipate) the heat generated from the semiconductor package (the first heat conductive member) both in the direction in which the cut portion is not formed and in the direction in which the cut portion is formed (the direction in which the second heat conductive member is provided). In this way, it is possible to enhance the heat dissipation of the electronic device.

Preferably, in the electronic device of the first aspect, a second metal plate which is arranged on a side of the attachment surface of the substrate and a third heat conductive member which is arranged between the second metal plate and the semiconductor package are included. In this configuration, it is also possible to dissipate the heat generated in the semiconductor package to the second metal plate through the third heat conductive member. In this way, it is possible to enhance the heat dissipation of the electronic device.

Preferably, in the electronic device including the second metal plate and the third heat conductive member, the second metal plate has a function of pressing the substrate to a side of the first metal plate through the third heat conductive member and the semiconductor package. In this configuration, it is possible to prevent the second metal plate from failing to make contact with the third heat conductive member and to prevent the first protrusion portion (the first metal plate) from failing to make contact with the first heat conductive member. In this way, it is possible to more reduce the decrease in the heat dissipation of the electronic device.

Preferably, in the electronic device including the second metal plate and the third heat conductive member, the second metal plate includes a second protrusion portion which protrudes to a side of the semiconductor package and which is in contact with the third heat conductive member. In this configuration, for example, even when a plurality of semiconductor packages having a different thickness are attached to the substrate, the protrusion heights of a plurality of second protrusion portions are respectively set according to the thicknesses of the semiconductor packages in contact, and thus all the semiconductor packages can be easily brought into contact with the second metal plate (the second protrusion portion).

In the second metal plate, the second protrusion portion protruding to the side of the semiconductor package is provided, and thus it is also possible to reduce the thickness of the third heat conductive member. In this way, it is possible to enhance the heat dissipation of the electronic device and reduce the cost of the third heat conductive member.

Preferably, in the electronic device of the first aspect, a plurality of the semiconductor packages and a plurality of the first heat conductive members are provided, and at least two of the first heat conductive members are formed to have the same thickness and are in contact with the one first protrusion portion. As described above, even when a plurality of the semiconductor packages and a plurality of the first heat conductive members are provided, in the electronic device of the first aspect, regardless of whether a plurality of semiconductor packages have a different thickness, at least two of the first heat conductive members can be formed to have the same thickness and can be in contact with the one first protrusion portion.

Preferably, in the electronic device of the first aspect, a heat dissipation fin is provided in the first metal plate. In this way, it is possible to more reduce the decrease in the heat dissipation of the electronic device.

Preferably, in the electronic device in which the heat dissipation fin is provided in the first metal plate, the heat dissipation fin is formed by cutting out the first metal plate. In this configuration, it is possible to easily form the heat dissipation fin in the first metal plate.

Preferably, in the electronic device of the first aspect, the first protrusion portion includes a contact portion which is in contact with the substrate through the first heat dissipation member, and a through hole is formed in the contact portion. In this configuration, when the substrate is attached to the first metal plate, it is possible to determine, from the side of the first metal plate, whether or not the first heat conductive member is arranged on the surface on the opposite side of the attachment surface of the substrate.

Preferably, in the electronic device of the first aspect, at least one of a screw and a band are provided which are attached to the substrate and the first metal plate and which press a center portion of the substrate to the side of the first metal plate. In this configuration, it is possible to more reliably bring the first protrusion portion into contact with the substrate (the first heat conductive member).

Preferably, in the electronic device of the first aspect, a first adhesive layer which adheres the substrate to the first metal plate is included. In this configuration, it is possible to prevent the first metal plate from separating from the substrate, with the result that it is possible to more reliably bring the first protrusion portion into contact with the substrate (the first heat conductive member).

Preferably, in the electronic device of the first aspect, a third protrusion portion protruding to the side of the substrate is provided in a position of the first metal plate corresponding to an edge portion of the substrate, and the edge portion of the substrate is attached to the third protrusion portion of the first metal plate. In this configuration, it is possible to form a gap between the center portion of the substrate and the first metal plate.

Preferably, in the electronic device in which the third protrusion portion is provided in the first metal plate, between the third protrusion portion and the substrate, a first elastic member for adjusting a distance from the first metal plate to the substrate is provided. In this configuration, since the distance from the first protrusion portion to the substrate can be adjusted, it is possible to adjust the contact pressure between the first protrusion portion and the substrate.

Preferably, in the electronic device of the first aspect, the first protrusion portion is attached to the first metal plate through a second elastic member for adjusting a distance from the first protrusion portion to the first metal plate. In this configuration, since the distance from the first protrusion portion to the first metal plate can be adjusted, it is possible to adjust the distance from the first protrusion portion to the substrate. In this way, it is possible to adjust the contact pressure between the first protrusion portion and the substrate.

Preferably, in the electronic device of the first aspect, a second adhesive layer is arranged between the first heat conductive member and the first protrusion portion. In this configuration, since it is possible to maintain satisfactory contact between the first heat conductive member and the first protrusion portion, it is possible to more easily transmit (dissipate) the heat generated in the semiconductor package to the first protrusion portion. In this way, it is possible to more enhance the heat dissipation of the electronic device.

According to a second aspect of the present invention, there is provided a display device that includes the electronic device configured as described above. In this configuration, it is possible to obtain a display device that can reduce the decrease in the heat dissipation.

### Advantages of the Invention

As described above, according to the present invention, it is possible to easily obtain an electronic device and a display device that can reduce the decrease in heat dissipation.

### BRIEF DESCRIPTION OF DRAWINGS

FIG. 1 A cross-sectional view showing the structure of a liquid crystal display device according to a first embodiment of the present invention;

FIG. 2 A cross-sectional view showing the structure of the vicinity of a substrate shown in FIG. 1;

FIG. 3 A cross-sectional view showing the structure of the substrate shown in FIG. 1;

FIG. 4 A cross-sectional view showing the structure of the vicinity of a substrate of a liquid crystal display device according to a second embodiment of the present invention;

FIG. 5 A plan view for illustrating the structure of a chassis shown in FIG. 4;

FIG. 6 A cross-sectional view for illustrating the structure of the chassis shown in FIG. 4;

FIG. 7 A plan view for illustrating the structure of the chassis shown in FIG. 4;

FIG. 8 A cross-sectional view showing the structure of the vicinity of a chassis of a liquid crystal display device according to a third embodiment of the present invention;

FIG. 9 A bottom view for illustrating the structure of the vicinity of the chassis shown in FIG. 8;

FIG. 10 A cross-sectional view showing the structure of the vicinity of a substrate of a liquid crystal display device according to a fourth embodiment of the present invention;

FIG. 11 A cross-sectional view showing the structure of the vicinity of a substrate of a liquid crystal display device according to a fifth embodiment of the present invention;

FIG. 12 A cross-sectional view showing the structure of the vicinity of a substrate of a liquid crystal display device according to a sixth embodiment of the present invention;

FIG. 13 An enlarged cross-sectional view for illustrating the structure of the vicinity of the substrate shown in FIG. 12;

FIG. 14 A cross-sectional view showing the structure of the substrate shown in FIG. 12;

FIG. 15 A cross-sectional view showing the structure of the vicinity of a substrate of a liquid crystal display device according to a seventh embodiment of the present invention;

FIG. 16 An enlarged cross-sectional view for illustrating the structure of the vicinity of the substrate shown in FIG. 15;

FIG. 17 A cross-sectional view showing the structure of the substrate shown in FIG. 15;

FIG. 18 A cross-sectional view showing the structure of the vicinity of a substrate of a liquid crystal display device according to an eighth embodiment of the present invention;

FIG. 19 A cross-sectional view showing the structure of the vicinity of a substrate of a liquid crystal display device according to a ninth embodiment of the present invention;

FIG. 20 An enlarged cross-sectional view for illustrating the structure of the vicinity of the substrate shown in FIG. 19;

FIG. 21 A cross-sectional view showing the structure of the vicinity of a substrate of a liquid crystal display device according to a tenth embodiment of the present invention;

FIG. 22 A cross-sectional view for illustrating the structure of the vicinity of a chassis shown in FIG. 21;

FIG. 23 A cross-sectional view showing the structure of a chassis of a liquid crystal display device according to a first variation of the present invention;

FIG. 24 A plan view for illustrating the structure of a chassis of a liquid crystal display device according to a second variation of the present invention;

FIG. 25 A bottom view showing the structure of the vicinity of a chassis of a liquid crystal display device according to a third variation of the present invention;

FIG. 26 A bottom view showing the structure of the vicinity of a chassis of a liquid crystal display device according to a fourth variation of the present invention;

FIG. 27 A cross-sectional view showing the structure of the vicinity of a substrate of a liquid crystal display device according to a fifth variation of the present invention;

FIG. 28 A cross-sectional view showing the structure of the vicinity of a heat dissipation sheet of a liquid crystal display device according to a sixth variation of the present invention;

FIG. 29 A plan view showing the structure of the heat dissipation sheet and an adhesive layer shown in FIG. 28;

FIG. 30 A cross-sectional view showing the structure of a protrusion portion of a liquid crystal display device according to a seventh variation of the present invention;

FIG. 31 A cross-sectional view showing the structure of a protrusion portion of a liquid crystal display device according to an eighth variation of the present invention;

FIG. 32 A cross-sectional view showing the structure of a protrusion portion of a liquid crystal display device according to a ninth variation of the present invention;

FIG. 33 A cross-sectional view showing the structure of the vicinity of a protrusion portion of a liquid crystal display device according to a tenth variation of the present invention;

FIG. 34 A cross-sectional view showing the structure of the vicinity of a protrusion portion of a liquid crystal display device according to an eleventh variation of the present invention;

FIG. 35 A cross-sectional view showing the structure of a heat dissipation fin of a liquid crystal display device according to a twelfth variation of the present invention;

FIG. 36 A cross-sectional view showing the structure of a protrusion portion of a liquid crystal display device according to a thirteenth variation of the present invention;

FIG. 37 A cross-sectional view showing the structure of a protrusion portion of a liquid crystal display device according to a fourteenth variation of the present invention;

FIG. 38 A cross-sectional view showing the structure of the vicinity of a substrate of a liquid crystal display device according to a fifteenth variation of the present invention;

FIG. 39 A cross-sectional view showing the structure of the vicinity of a substrate of a liquid crystal display device according to a sixteenth variation of the present invention;

FIG. 40 A cross-sectional view showing the structure of an electronic device of a conventional example; and

FIG. 41 A cross-sectional view for illustrating the structure of the electronic device of the conventional example shown in FIG. 40.

### DESCRIPTION OF EMBODIMENTS

Embodiments of the present invention will be described below with reference to accompanying drawings. For ease of understanding, hatching may not be performed even in a cross-sectional view, and hatching may be performed even in a plan view.

### First Embodiment

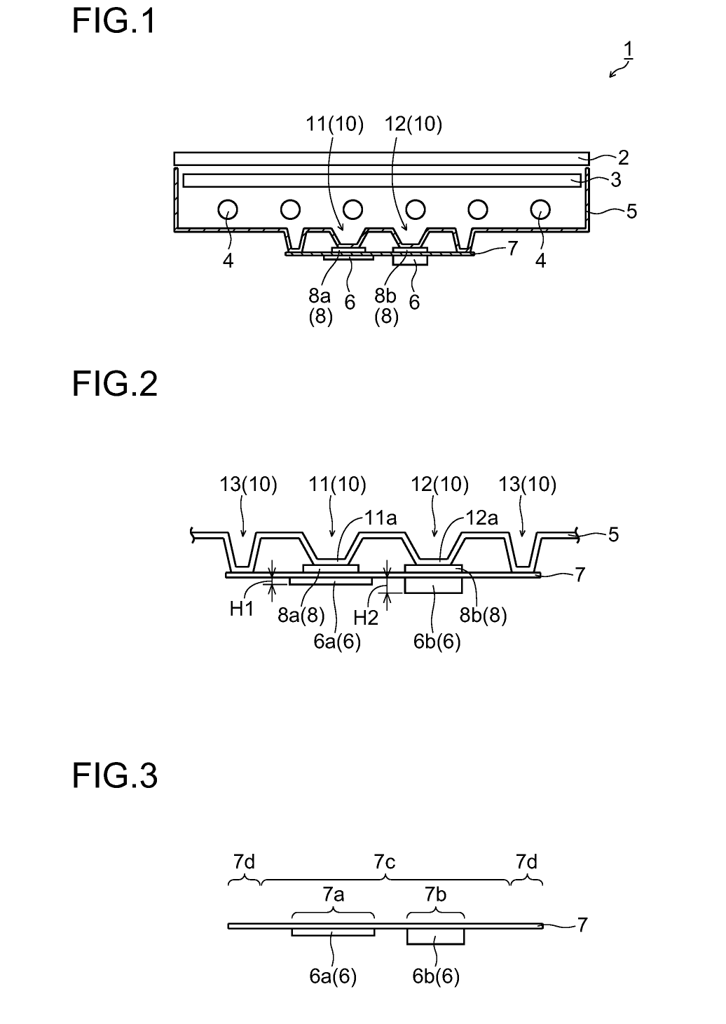

The structure of a liquid crystal display device 1 according to a first embodiment of the present invention will be described with reference to FIGS. 1 to 3.

The liquid crystal display device 1 according to the first embodiment of the present invention forms, for example, a liquid crystal television set (not shown). As shown in FIG. 1, the liquid crystal display device 1 is configured to include: a liquid crystal display panel 2; an optical sheet 3 and a plurality of light sources 4 that are arranged on the rear surface (back surface) side of the liquid crystal display panel 2; a chassis 5 that holds the optical sheet 3 and the light sources 4 and that is formed with a metal sheet; a plurality of semiconductor packages 6 that are arranged outside the chassis 5; a substrate 7 that is arranged opposite the chassis 5 to which the semiconductor packages 6 are attached; and a heat dissipation sheet (heat conductive sheet) 8 that is arranged between the chassis 5 and the substrate 7. The optical sheet 3, the light sources 4, the chassis 5 and the like constitute a direct-type backlight device. The liquid crystal display device 1 is an example of an “electronic device” and a “display device” according to the present invention; the chassis 5 is an example of a “first metal plate.” The heat dissipation sheet 8 (8a and 8b) is an example of a “first heat conductive member.”

The liquid crystal display panel 2 is formed with two glass substrates that sandwich an unillustrated liquid crystal layer. The liquid crystal display panel 2 functions as a display panel by being illuminated by the light sources 4.

The optical sheet 3 is formed with, for example, a plurality of sheets such as a prism sheet and a lens sheet.

The light source 4 is formed with, for example, a fluorescent lamp. The light source 4 may be formed with, for example, an LED (light emitting diode) other than a fluorescent lamp. On the back surface side of the light sources 4, a reflective sheet (not shown) may be arranged.

Here, in the first embodiment, as shown in FIG. 2, a plurality of ribs 10 that protrude to the side of the substrate 7 (the outside) are formed. The ribs 10 are formed by, for example, squeezing processing.

The ribs 10 include ribs 11 and 12 that are in contact with the semiconductor packages 6 through the heat dissipation sheet 8 and a plurality of ribs 13. The ribs 11 and 12 are an example of a “first protrusion portion” according to the present invention; the rib 13 is an example of a “third protrusion portion” according to the present invention.

The ribs 11 and 12 are formed so as to have the same protrusion height (height in the thickness direction).

The rib 11 is formed in a position (a position opposite an element mounting portion 7a (see FIG. 3) described later of the substrate 7) corresponding to the semiconductor package 6a described later; the rib 12 is formed in a position (a position opposite an element mounting portion 7b (see FIG. 3) described later of the substrate 7) corresponding to the semiconductor package 6b described later. In the ribs 11 and 12, contact portions 11a and 12a that are in contact with the substrate 7 through the heat dissipation sheet 8 are respectively provided. For example, the contact portions 11a and 12a are formed to be flat.

A plurality of ribs 13 are arranged in the positions of the chassis 5 (positions directly above edge portions 7d) corresponding to edge portions 7d (see FIG. 3) described later of the substrate 7. The ribs 13 are formed so as to have the same protrusion height. The ribs 13 have a greater protrusion height than the rib 11 and 12. The protrusion height of the ribs 13 is set substantially equal to the total of the protrusion height of the rib 11 (or the rib 12) and the thickness of the heat dissipation sheet 8a (or the heat dissipation sheet 8b) described later.

A plurality of semiconductor packages 6 are elements for performing processing such as FRC (frame rate control), and generate a large amount of heat during its operation. The semiconductor packages 6 include the semiconductor packages 6a and 6b that have a different thickness. For example, the semiconductor package 6b has a larger thickness than the semiconductor package 6a.

A plurality of semiconductor packages 6a and 6b are attached to the attachment surface of the substrate 7 with an unillustrated solder layer or the like. The attachment height (a distance from the attachment surface of the substrate 7 to the outer surface (the surface on the lower side of FIG. 2) of the semiconductor package 6b) H2 of the semiconductor package 6b is greater than the attachment height (a distance from the attachment surface of the substrate 7 to the outer surface (the surface on the lower side of FIG. 2) of the semiconductor package 6a) H1 of the semiconductor package 6a.

As shown in FIG. 3, the substrate 7 includes: a center portion 7c that includes element mounting portions 7a and 7b to which a plurality of semiconductor packages 6a and 6b are respectively attached; and the edge portions 7d (portions other than the center portion 7c).

Heat generated in the semiconductor packages 6a and 6b is transmitted through an unillustrated solder layer or the like to the substrate 7. In order to transmit the heat in the direction of the thickness of the substrate 7, through holes (not shown) filled with metal material may be provided in the element mounting portions 7a and 7b of the substrate 7.

As shown in FIG. 2, the rear surfaces (the surfaces on the opposite side of the attachment surface) of the edge portions 7d of the substrate 7 are fixed to the ribs 13 of the chassis 5 with an unillustrated screw or the like.

The heat dissipation sheet 8 is formed with a sheet member having a high thermal conductivity. The heat dissipation sheet 8 is formed such that it can be compressed by being pressed and that it can be elastically deformed. Specifically, the heat dissipation sheet 8 is formed of silicone rubber, acryl rubber or the like; the Asker C hardness of the heat dissipation sheet 8 is, for example, about 10 to 60.

A plurality of heat dissipation sheets 8 include the heat dissipation sheet 8a arranged on the rear surface of the element mounting portion 7a of the substrate 7 and the heat dissipation sheet 8b arranged on the rear surface of the element mounting portion 7b of the substrate 7.

The element mounting portion 7a of the substrate 7 is in contact with the contact portion 11a of the rib 11 through the heat dissipation sheet 8a; the element mounting portion 7b of the substrate 7 is in contact with the contact portion 12a of the rib 12 through the heat dissipation sheet 8b.

In the first embodiment, as described above, the heat dissipation sheet 8 is provided between the ribs 11 and 12 of the chassis 5 and the substrate 7, and thus the heat generated in the semiconductor packages 6 can be dissipated to the chassis 5 through the substrate 7 and the heat dissipation sheet 8 (8a and 8b).

In the first embodiment, for example, even if variations in manufacturing cause the attachment height of the semiconductor packages 6 (6a and 6b) to become less than a design value, since the distance from the ribs 11 and 12 to the substrate 7 is not changed, it is possible to prevent the ribs 11 and 12 from being brought out of contact with the substrate 7 (the heat dissipation sheet 8). Thus, it is possible to reduce the decrease in the heat dissipation of the liquid crystal display device 1.

In the first embodiment, as described above, the ribs 11 and 12 protruding to the side of the substrate 7 are provided in the chassis 5, and thus it is possible to reduce the thickness of the heat dissipation sheet 8 (8a and 8b). In this way, it is possible to enhance the heat dissipation of the liquid crystal display device 1 and reduce the cost of the heat dissipation sheet 8 (8a and 8b).

In the first embodiment, since the heat generated in the semiconductor packages 6 can be dissipated to the side of the back surface (the surface on the opposite side of the attachment surface) of the substrate 7, unlike the case where the heat generated in the semiconductor packages 6 is dissipated to the side of the attachment surface of the substrate 7, a dissipation member or the like may not be provided on the side of the attachment surface of the substrate 7. Thus, it is possible to reduce the increase in the size of the liquid crystal display device 1 as a whole.

In the first embodiment, as described above, the ribs 13 protruding to the side of the substrate 7 are provided in the positions of the chassis 5 corresponding to the edge portions 7d of the substrate 7, and the edge portions 7d of the substrate 7 are attached to the ribs 13 of the chassis 5. Thus, it is possible to form a gap between the center portion 7c of the substrate 7 and the chassis 5.

In the first embodiment, since the semiconductor packages 6 generates a large amount of heat, it is particularly effective to configure the liquid crystal display device 1 as described above.

### Second Embodiment

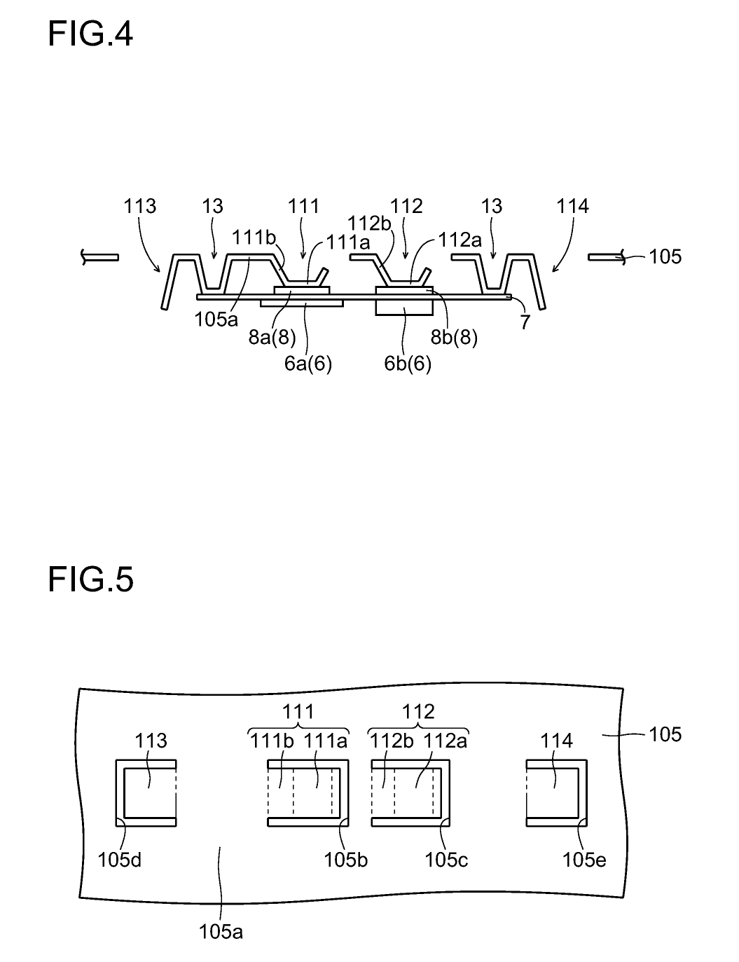

In a second embodiment, a case where, unlike the first embodiment, spring portions 111b and 112b are provided in order to bring the substrate 7 (the heat dissipation sheet 8) into contact with contact portions 111a and 112a will be described with reference to FIGS. 4 to 7.

In the second embodiment, as shown in FIG. 4, in a chassis 105, a plurality of protrusion portions 111 and 112 protruding to the side of the substrate 7 (the outside), a plurality of ribs 13 and a plurality of fin portions 113 and 114 functioning as heat dissipation fins are formed. The chassis 105 is an example of the “first metal plate” according to the present invention; the protrusion portions 111 and 112 are an example of the “first protrusion portion” and a “heat dissipation fin” according to the present invention. The fin portions 113 and 114 are an example of the “heat dissipation fin” according to the present invention.

A plurality of protrusion portions 111 and 112 are in contact with the substrate 7 through the heat dissipation sheet 8. The protrusion portions 111 and 112 are formed so as to have the same protrusion height.

The protrusion portion 111 is formed in a position (a position opposite the element mounting portion 7a of the substrate 7) corresponding to the semiconductor package 6a; the protrusion portion 112 is formed in a position (a position opposite the element mounting portion 7b of the substrate 7) corresponding to the semiconductor package 6b.

Here, in the second embodiment, the protrusion portion 111 includes a contact portion 111a that is in contact with the semiconductor package 6 (the heat dissipation sheet 8) and a spring portion 111b that applies a force acting toward the side of the substrate 7 to the contact portion 111a. This spring portion 111b connects the contact portion 111a to a flat surface portion 105a (a portion of the chassis 105 other than the protrusion portions 111 and 112, the ribs 13 and the fin portions 113 and 114) of the chassis 105.

Likewise, the protrusion portion 112 includes a contact portion 112a that is in contact with the semiconductor package 6 (the heat dissipation sheet 8) and a spring portion 112b that applies a force acting toward the side of the substrate 7 to the contact portion 112a. This spring portion 112b connects the contact portion 112a to the flat surface portion 105a of the chassis 105.

The protrusion portions 111 and 112 are formed by partially cutting out parts of the chassis 105 and bending them. Specifically, as shown in FIG. 5, around the protrusion portions 111 and 112, for example, U-shaped cut portions 105b and 105c are respectively formed. Then, the cut portions 105b and 105c are formed by being bent in positions represented by broken lines of FIG. 5.

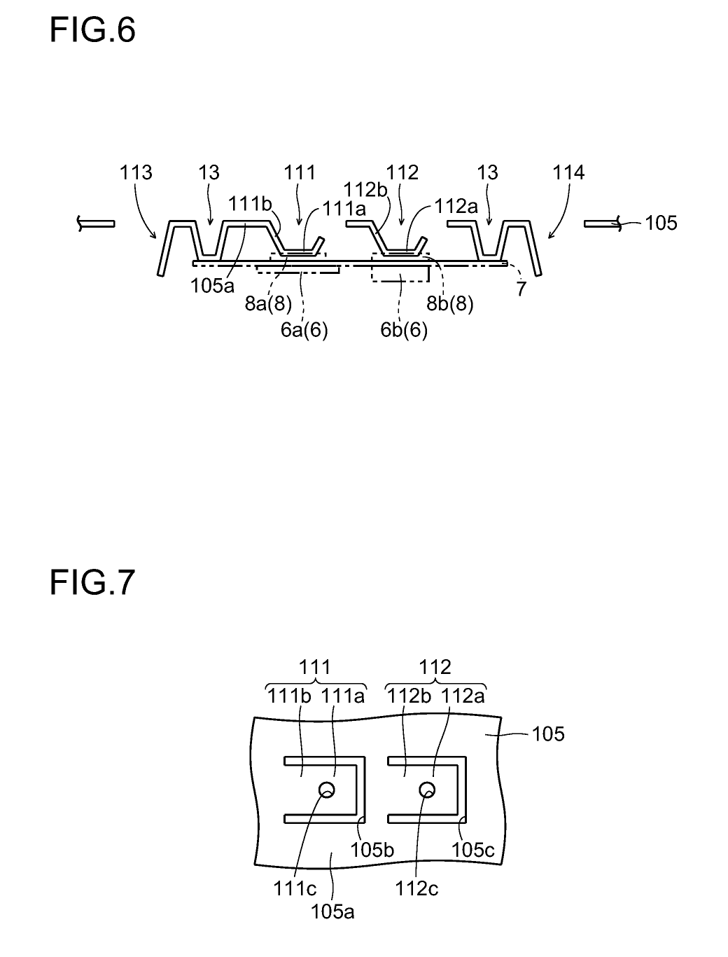

In the second embodiment, as shown in FIG. 6, with the substrate 7 unfixed to the chassis 105, the contact portion 111a of the protrusion portion 111 is formed so as to be arranged outside (below) a position where the upper surface (front surface) of the heat dissipation sheet 8a is to be arranged. Thus, with the substrate 7 fixed to the chassis 105 (the state of FIG. 4), the contact portion 111a can be reliably brought into contact with the heat dissipation sheet 8a (the substrate 7).

Since, with the substrate 7 fixed to the chassis 105, the spring portion 111b of the protrusion portion 111 is elastically deformed, it is possible to prevent a contact pressure on the heat dissipation sheet 8a (the substrate 7) of the contact portion 111a from being excessively increased.

Likewise, with the chassis 105 unfixed to the substrate 7, the contact portion 112a of the protrusion portion 112 is formed so as to be arranged outside (below) a position where the upper surface (front surface) of the heat dissipation sheet 8b is to be arranged. Thus, with the substrate 7 fixed to the chassis 105, the contact portion 112a can be reliably brought into contact with the heat dissipation sheet 8b (the substrate 7).

Since, with the substrate 7 fixed to the chassis 105, the spring portion 112b of the protrusion portion 112 is elastically deformed, it is possible to prevent a contact pressure on the heat dissipation sheet 8b (the substrate 7) of the contact portion 112a from being excessively increased.

As shown in FIG. 7, in the contact portions 111a and 112a, through holes 111c and 112c may be respectively formed. The through holes 111c and 112c may be formed in the shape of a circle, a triangle, a quadrangle or the like.

A plurality of fin portions 113 and 114 are formed by partially cutting out parts of the chassis 105 and bending them. Specifically, as shown in FIG. 5, around the fin portions 113 and 114, for example, U-shaped cut portions 105d and 105e are respectively formed. Then, the cut portions 105d and 105e are formed by being bent in positions represented by alternate long and two short dashes lines of FIG. 5.

Since the fin portions 113 and 114 are bent and thus the gap between the fin portions 113 and 114 and the flat surface portion 105a of the chassis 105 is made larger, air passes (flows) more smoothly. Since the fin portions 113 and 114 are provided in the portion where air passes more smoothly, it is possible to more enhance the heat dissipation.

In the second embodiment, the gap is formed around the protrusion portions 111 and 112, and the protrusion portions 111 and 112 function as heat dissipation fins.

In order to further enhance the heat dissipation, a heat dissipation fan (not shown) may be provided separately. In this case, the heat dissipation fan is preferably arranged such that air directly hits the protrusion portions 111 and 112 and the fin portions 113 and 114.

The structure of the other portions in the second embodiment is the same as in the first embodiment.

In the second embodiment, as described above, in the protrusion portions 111 and 112, the contact portions 111a and 112a that are brought into contact with the substrate 7 through the heat dissipation sheet 8 and the spring portions 111b and 112b that apply a force acting toward the side of the substrate 7 to the contact portions 111a and 112a are provided. Thus, since, with the spring portions 111b and 112b, it is possible to apply a force acting toward the side of the substrate 7 to the contact portions 111a and 112a, it is possible to more reliably bring the contact portions 111a and 112a into contact with the substrate 7 (the heat dissipation sheet 8).

In the second embodiment, as described above, the protrusion portions 111 and 112 are formed by bending the chassis 105. Thus, it is possible to easily form, in the chassis 105, the protrusion portions 111 and 112 protruding to the side of the substrate 7 and to easily form, in the protrusion portions 111 and 112, the spring portions 111b and 112b that apply a force acting toward the side of the substrate 7 to the contact portions 111a and 112a.

In the second embodiment, as described above, it is possible to easily form the protrusion portions 111 and 112 by forming the cut portions 105b and 105c around the protrusion portions 111 and 112 of the chassis 105 and bending the chassis 105. It is also possible to form the protrusion portions 111 and 112 in desired positions of the chassis 105.

In the second embodiment, as described above, it is possible to more enhance the heat dissipation of the liquid crystal display device by providing the fin portions 113 and 114 in the chassis 105.

Furthermore, in the second embodiment, since the protrusion portions 111 and 112 also function as heat dissipation fins, it is possible to further enhance the heat dissipation of the liquid crystal display device.

In the second embodiment, as described above, the through holes 111c and 112c are formed in the contact portions 111a and 112a, and thus, when the substrate 7 is attached to the chassis 105, it is possible to determine, from the side of the chassis 105, whether or not the heat dissipation sheet 8 (8a and 8b) is arranged on the surface on the opposite side of the attachment surface of the substrate 7.

The other effects of the second embodiment are the same as those of the first embodiment.

### Third Embodiment

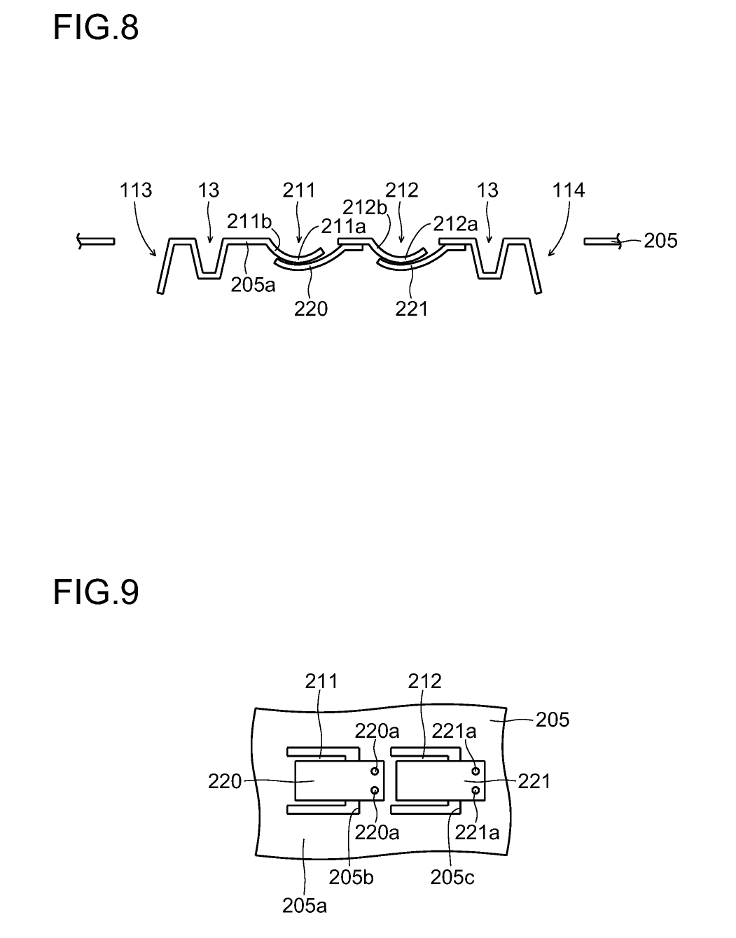

In a third embodiment, a case where, unlike the second embodiment, plate springs 220 and 221 are attached to a chassis 205 will be described with reference to FIGS. 8 and 9.

In the third embodiment, as shown in FIG. 8, in the chassis 205, a plurality of protrusion portions 211 and 212 protruding to the side of the substrate 7 (the outside), a plurality of ribs 13 and a plurality of fin portions 113 and 114 are formed. The chassis 205 is an example of the “first metal plate” according to the present invention; the protrusion portions 211 and 212 are examples of the “first protrusion portion” and the “heat dissipation fin” according to the present invention.

A plurality of protrusion portions 211 and 212 are formed to have the same protrusion height.

The protrusion portion 211 is formed in a position corresponding to the semiconductor package 6a; the protrusion portion 212 is formed in a position corresponding to the semiconductor package 6b.

The protrusion portion 211 includes a contact portion 211a and a spring portion 211b that applies a force acting toward the side of the substrate 7 to the contact portion 211a. Likewise, the protrusion portion 212 includes a contact portion 212a and a spring portion 212b that applies a force acting toward the side of the substrate 7 to the contact portion 212a.

As shown in FIG. 9, around the protrusion portions 211 and 212, U-shaped cut portions 205b and 205c are respectively formed, and the protrusion portions 211 and 212 are formed by curving part of the chassis 205.

Here, in the third embodiment, onto predetermined regions of the chassis 205, the plate springs 220 and 221 formed of, for example, copper or aluminum are attached. The plate springs 220 and 221 are an example of a “second heat conductive member” according to the present invention.

Specifically, the plate spring 220 is arranged across the cut portion 205b. The plate spring 220 is curved, and is formed so as to be sandwiched between the protrusion portion 211 and the heat dissipation sheet 8 (the substrate 7).

The plate spring 220 is fixed to the flat surface portion 205a (a portion of the chassis 205 other than the protrusion portions 211 and 212, the ribs 13 and the fin portions 113 and 114) of the chassis 205 by, for example, the spot welding of a weld portion 220a. Then, the plate spring 220 is brought into contact with the protrusion portion 211 and the flat surface portion 205a of the chassis 205. The flat surface portion 205a is an example of a “portion of the first metal plate other than the first protrusion portion” according to the present invention.

Likewise, the plate spring 221 is arranged across the cut portion 205c. The plate spring 221 is curved, and is formed so as to be sandwiched between the protrusion portion 212 and the heat dissipation sheet 8 (the substrate 7).

The plate spring 221 is fixed to the flat surface portion 205a of the chassis 205 by, for example, the spot welding of a weld portion 221a. Then, the plate spring 221 is brought into contact with the protrusion portion 212 and the flat surface portion 205a of the chassis 205.

With the substrate 7 unfixed to the chassis 205, the plate springs 220 and 221 are formed so as to be arranged outside (below) a position where the upper surface (front surface) of the heat dissipation sheet 8 is to be arranged. Thus, with the substrate 7 fixed to the chassis 205, the contact portion 211a can be reliably brought into contact with the heat dissipation sheet 8 (the substrate 7) through the plate spring 220, and the contact portion 212a can be reliably brought into contact with the heat dissipation sheet 8 (the substrate 7) through the plate spring 221.

Although, in the figure, the plate springs 220 and 221 are formed in the shape of a rectangle as seen in plan view, they may be formed in the shape of a triangle, a circle, a polygon or the like.

The protrusion portion 211 may be arranged so as to be sandwiched between the plate spring 220 and the heat dissipation sheet 8 (the substrate 7). Likewise, the protrusion portion 212 may be arranged so as to be sandwiched between the plate spring 221 and the heat dissipation sheet 8 (the substrate 7).

The structure of the other portions in the third embodiment is the same as in the first and second embodiments.

In the third embodiment, as described above, in the chassis 205, the plate spring 220 that is placed across the cut portion 205b and that is brought into contact with the protrusion portion 211 and the flat surface portion 205a of the chassis 205 are provided. Here, when the cut portion 205b is formed around the protrusion portion 211, though the heat from the semiconductor package 6a (the heat dissipation sheet 8a) is transmitted (dissipated) in the direction in which the cut portion 205b is not formed, as described above, the plate spring 220 is provided across the cut portion 205b, and thus the heat from the semiconductor package 6a (the heat dissipation sheet 8a) can be transmitted (dissipated) both in the direction in which the cut portion 205b is not formed and in the direction in which the cut portion 205b is formed (in the direction in which the plate spring 220 is formed). Thus, it is possible to enhance the heat dissipation of the liquid crystal display device.

Likewise, in the chassis 205, the plate spring 221 that is placed across the cut portion 205c and that is brought into contact with the protrusion portion 212 and the flat surface portion 205a of the chassis 205 is provided. Here, when the cut portion 205c is formed around the protrusion portion 212, though the heat from the semiconductor package 6b (the heat dissipation sheet 8b) is transmitted (dissipated) in the direction in which the cut portion 205c is not formed, as described above, the plate spring 221 is provided across the cut portion 205c, and thus the heat from the semiconductor package 6b (the heat dissipation sheet 8b) can be transmitted (dissipated) both in the direction in which the cut portion 205c is not formed and in the direction in which the cut portion 205c is formed (in the direction in which the plate spring 221 is formed). Thus, it is possible to enhance the heat dissipation of the liquid crystal display device.

The other effects of the third embodiment are the same as those of the first and second embodiments.

### Fourth Embodiment

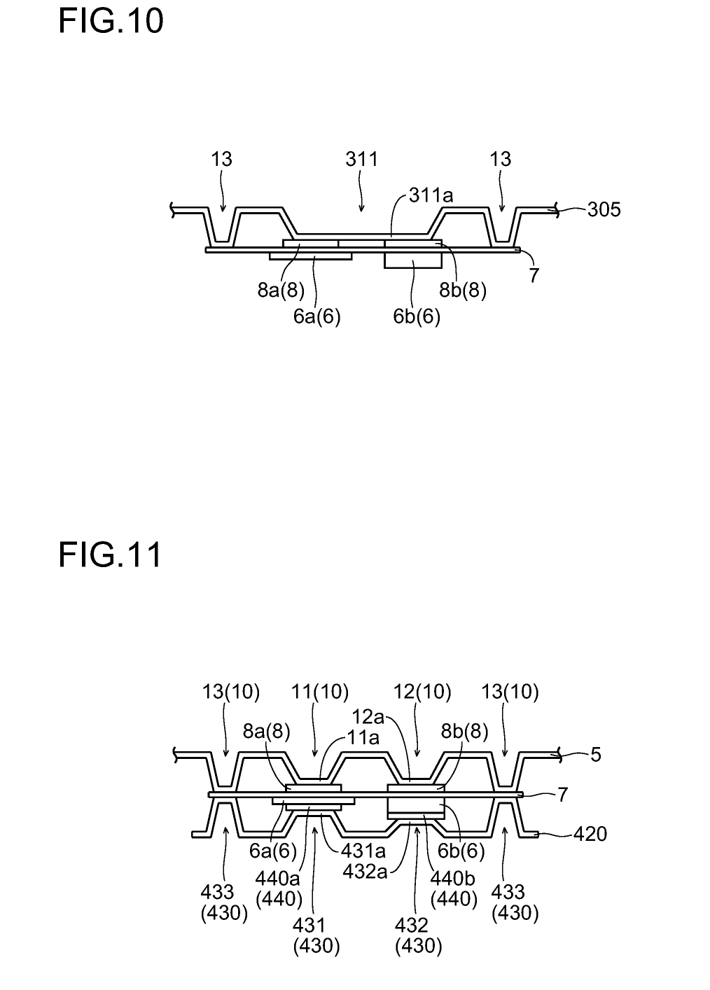

In a fourth embodiment, a case where, unlike the first to third embodiments, a plurality of heat dissipation sheets 8 are in contact with one rib 311 will be described with reference to FIG. 10.

In the fourth embodiment, as shown in FIG. 10, in a chassis 305, the rib 311 protruding to the side of the substrate 7 (the outside) and a plurality of ribs 13 are formed. The chassis 305 is an example of the “first metal plate” according to the present invention; the rib 311 is an example of the “first protrusion portion” according to the present invention

The rib 311 is formed such that, for example, the rib 11 and the rib 12 of the first embodiment are formed into one piece. Specifically, the rib 311 is formed in a position corresponding to the semiconductor packages 6a and 6b. In the rib 311, a contact portion 311a in contact with the heat dissipation sheets 8a and 8b is formed. The contact portion 311a is formed so as to be parallel to the substrate 7.

The structure of the other portions in the fourth embodiment is the same as in the first embodiment.

In the fourth embodiment, as described above, the heat dissipation sheets 8a and 8b are formed to have the same thickness, and are brought into contact with the one rib 311. As described above, even when the a plurality of heat dissipation sheets 8a and 8b are provided, in the fourth embodiment, the heat dissipation sheets 8a and 8b can be formed to have the same thickness and be brought into contact with the one rib 311.

The other effects of the fourth embodiment are the same as those of the first embodiment.

### Fifth Embodiment

In a fifth embodiment, a case where, unlike the first to fourth embodiments, heat is also dissipated from the lower side (the opposite side of the substrate 7) of the semiconductor packages 6 will be described with reference to FIG. 11.

In the fifth embodiment, as shown in FIG. 11, on the side of the attachment surface of the substrate 7, a pressing member 420 formed with a metal sheet is provided, and a dissipation sheet 440 is arranged between the semiconductor package 6 and the pressing member 420. The pressing member 420 is an example of a “second metal plate” according to the present invention. The heat dissipation sheet 440 (440a and 440b) is an example of a “third heat conductive member” according to the present invention.

The pressing member 420 has the function of pressing the substrate 7 to the side of the chassis 5 through the heat dissipation sheet 440 and the semiconductor packages 6. In the pressing member 420, a plurality of ribs 430 protruding to the side of the substrate 7 (the inside) are formed. The ribs 430 are formed by, for example, squeezing processing.

The ribs 430 includes ribs 431 and 432 in contact with the semiconductor packages 6 through the heat dissipation sheet 440 and a plurality of ribs 433 arranged in the positions of the pressing member 420 corresponding to the edge portions 7d of the substrate 7. The ribs 431 and 432 are an example of a “second protrusion portion” according to the present invention.

The ribs 431 and 432 are formed so as to have a different protrusion height; for example, the rib 432 has a smaller protrusion height than the rib 431.

The rib 431 is formed in a position opposite the semiconductor package 6a; the rib 432 is formed in a position opposite the semiconductor package 6b. In the ribs 431 and 432, contact portions 431a and 432a that are in contact with the semiconductor packages 6 (the heat dissipation sheet 440) are respectively provided. For example, the contact portions 431a and 432a are formed to be flat.

A plurality of ribs 433 are formed so as to have the same protrusion height. The ribs 433 have a greater protrusion height than the ribs 431 and 432. The protrusion height of the ribs 433 is equal to the total value of the protrusion height of the rib 431 (or the rib 432), the thickness of a heat dissipation sheet 440a (or a dissipation sheet 440b) described later and the thickness of the semiconductor package 6a (or the semiconductor package 6b) or is slightly less than the total value.

The heat dissipation sheet 440 is formed with a sheet member having a high thermal conductivity. The heat dissipation sheet 440 is formed such that it can be compressed by being pressed and that it can be elastically deformed. Specifically, the heat dissipation sheet 440 is formed of silicone rubber, acryl rubber or the like; the Asker C hardness of the heat dissipation sheet 440 is, for example, about 10 to 60.

A plurality of heat dissipation sheets 440 include the heat dissipation sheet 440a arranged on the external surface (the lower side surface) of the semiconductor package 6a and the heat dissipation sheet 440b arranged on the external surface (the lower side surface) of the semiconductor package 6b.

The semiconductor package 6a is in contact with the contact portion 431a of the rib 431 through the heat dissipation sheet 440a; the semiconductor package 6b is in contact with the contact portion 432a of the rib 432 through the heat dissipation sheet 440b.

The ribs 433 of the pressing member 420 and the edge portions 7d of the substrate 7 are fixed to the ribs 13 of the chassis 5 with an unillustrated screw or the like.

The structure of the other portions in the fifth embodiment is the same as in the first embodiment.

In the fifth embodiment, as described above, the pressing member 420 is arranged on the side of the attachment surface of the substrate 7, and the heat dissipation sheet 440 is provided between the pressing member 420 and the semiconductor packages 6. Thus, the heat generated in the semiconductor packages 6 can also be dissipated through the heat dissipation sheet 440 to the pressing member 420. In this way, it is possible to more enhance the heat dissipation of the liquid crystal display device.

In the fifth embodiment, as described above, the pressing member 420 has the function of pressing the substrate 7 to the side of the chassis 5 through the heat dissipation sheet 440 and the semiconductor packages 6. Thus, it is possible to prevent the pressing member 420 from failing to make contact with the heat dissipation sheet 440 and to prevent the ribs 11 and 12 from failing to make contact with the heat dissipation sheet 8. In this way, it is possible to more reduce the decrease in the heat dissipation of the liquid crystal display device.

The chassis 5 used in the liquid crystal display device 1 (electronic device) has a high strength and thus is unlikely to be deformed. Hence, when the substrate 7 is pressed by the pressing member 420, it is possible to reduce the bending of the chassis 5 to the opposite side (upper side) of the substrate 7. Thus, it is possible to reduce the possibility that the heat dissipation sheet 8 is unlikely to be brought into contact with the chassis 5.

Since the pressing member 420 has the function of pressing the substrate 7 to the side of the chassis 5, for example, even when variations in manufacturing cause the protrusion height of the rib 11 (or the rib 12) to become less than a design value or the thickness of the heat dissipation sheet 8 to become less than a design value, it is possible to bring, with the pressing member 420, the substrate 7 into contact with the rib 11 (or the rib 12) through the heat dissipation sheet 8.

In the fifth embodiment, as described above, in the pressing member 420, the ribs 431 and 432 that protrude to the side of the semiconductor packages 6 and that are in contact with the heat dissipation sheet 440 are provided. Thus, even when a plurality of semiconductor packages 6a and 6b having a different thickness are attached to the substrate 7, the protrusion heights of the ribs 431 and 432 are respectively set according to the thicknesses of the semiconductor packages 6a and 6b in contact, and thus all the semiconductor packages 6 (6a and 6b) can be easily brought into contact with the pressing member 420 (the ribs 431 and 432).

In the pressing member 420, the ribs 431 and 432 protruding to the side of the semiconductor packages 6 are provided, and thus it is possible to reduce the thickness of the heat dissipation sheet 440. In this way, it is possible to enhance the heat dissipation of the liquid crystal display device and reduce the cost of the heat dissipation sheet 440.

The other effects of the fifth embodiment are the same as those of the first embodiment.

### Sixth Embodiment

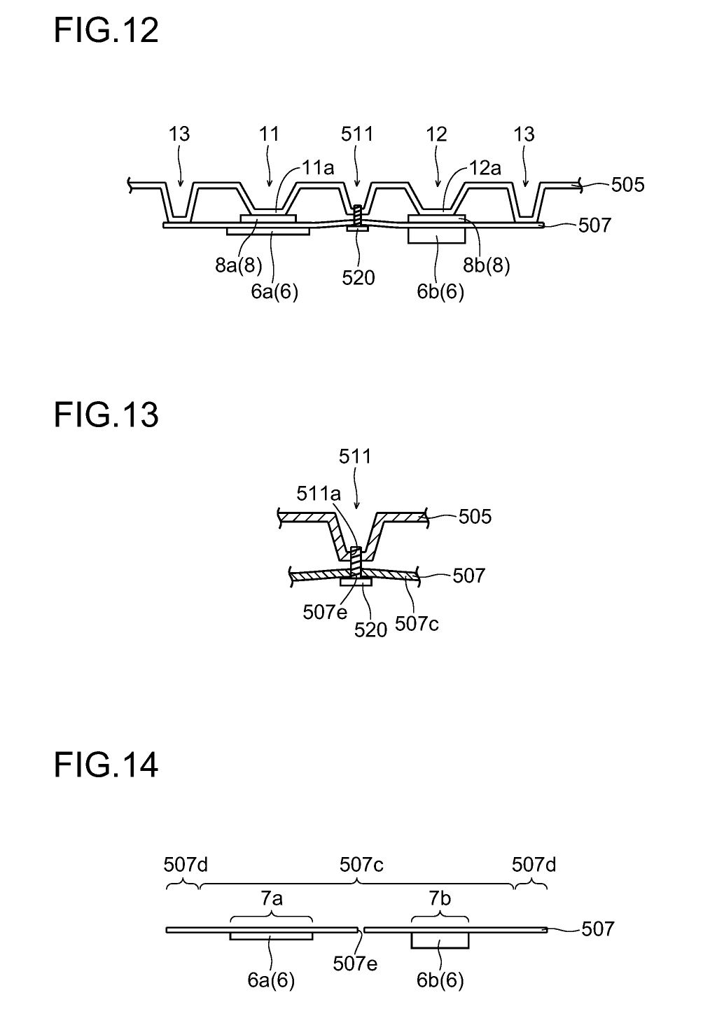

In a sixth embodiment, a case where, unlike the first to fifth embodiments, a screw 520 that presses a substrate 507 (the heat dissipation sheet 8) to the side of a chassis 505 is provided will be described with reference to FIGS. 12 and 14.

In the sixth embodiment, as shown in FIG. 12, in the chassis 505, a rib 511 protruding to the side of the substrate 507 (the outside) is formed between the rib 11 and the rib 12. The rib 511 has a protrusion height lower than a plurality of ribs 13. In the rib 511, as shown in FIG. 13, a screw hole 511a is formed. In the screw hole 511a, a screw thread may be formed. The chassis 505 is an example of the “first metal plate” according to the present invention.

In the center portion 507c of the substrate 507, a screw hole 507e is formed in a position corresponding to the screw hole 511a of the chassis 505. The screw 520 is attached through the screw hole 507e (the substrate 507) and the screw hole 511a (the chassis 505), and the screw 520 presses the center portion 507c (portion between the element mounting portions 7a and 7b (see FIG. 14)) of the substrate 507 to the side of the chassis 505. Hence, the center portion 507c (portion between the element mounting portions 7a and 7b) of the substrate 507 is curved to the side of the chassis 505.

The structure of the other portions in the sixth embodiment is the same as in the first embodiment.

In the sixth embodiment, as described above, the screw 520 that is attached through the substrate 507 and the chassis 505 is provided, and thus it is possible to more reliably bring, with the screw 520, the rib 11 and the rib 12 into contact with the substrate 507 (the heat dissipation sheet 8).

The other effects of the sixth embodiment are the same as those of the first embodiment.

### Seventh Embodiment

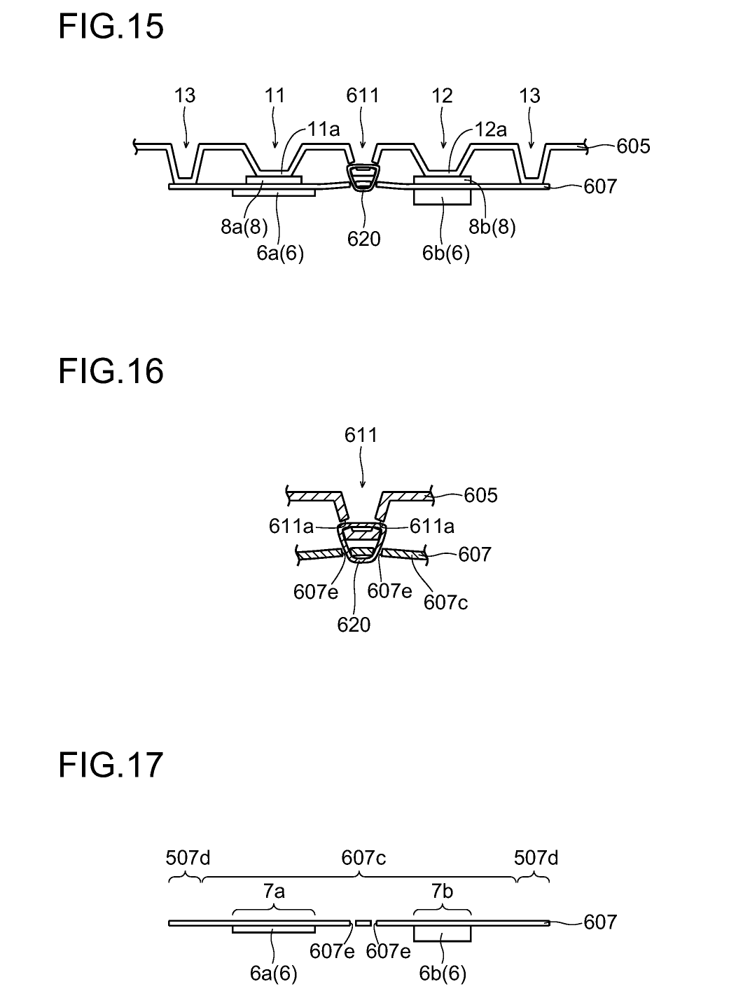

In a seventh embodiment, a case where, unlike the sixth embodiment, a band 620 that presses a substrate 607 (the heat dissipation sheet 8) to the side of a chassis 605 is provided will be described with reference to FIGS. 15 to 17.

In the seventh embodiment, as shown in FIG. 15, in the chassis 605, a rib 611 protruding to the side of the substrate 607 (the outside) is formed between the rib 11 and the rib 12. The rib 611 has a protrusion height lower than a plurality of ribs 13. In the rib 611, as shown in FIG. 16, a band attachment hole 611a is formed. The chassis 605 is an example of the “first metal plate” according to the present invention.

In the center portion 607c of the substrate 607, a band attachment hole 607e is formed in the vicinity of the band attachment hole 611a of the chassis 605. The band 620 is attached to the band attachment hole 607e and the band attachment hole 611a, and the band 620 presses the center portion 607c (portion between the element mounting portions 7a and 7b (see FIG. 17)) of the substrate 607 to the side of the chassis 605. Hence, the center portion 607c (portion between the element mounting portions 7a and 7b) of the substrate 607 is curved to the side of the chassis 605.

The band 620 may be formed with, for example, a binding band such as tielap (registered trademark) or may be formed with a heat compression band that is compressed by heat.

The structure of the other portions in the seventh embodiment is the same as in the sixth embodiment.

In the sixth embodiment, as described above, the band 620 that is attached to the substrate 607 and the chassis 605 is provided, and thus it is possible to more reliably bring, with the band 620, the rib 11 and the rib 12 into contact with the substrate 607 (the heat dissipation sheet 8).

The other effects of the seventh embodiment are the same as those of the sixth embodiment.

### Eighth Embodiment

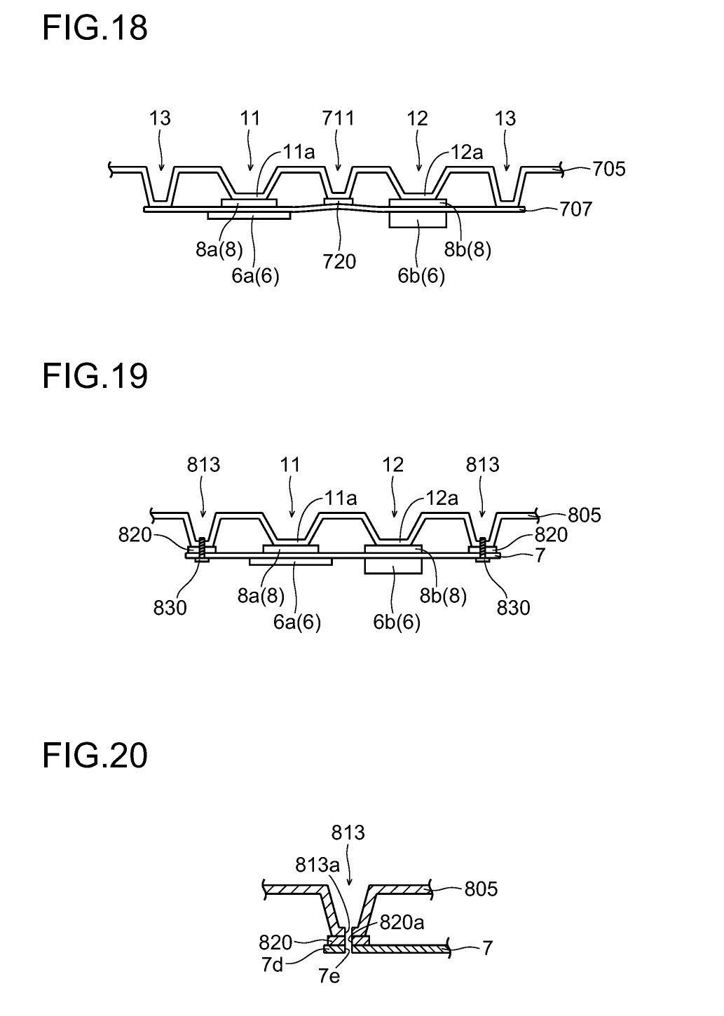

In an eighth embodiment, a case where, unlike the sixth and seventh embodiments, an adhesive layer 720 for pressing a substrate 707 (the heat dissipation sheet 8) to the side of a chassis 705 is provided will be described with reference to FIG. 18.

In the eighth embodiment, as shown in FIG. 18, in the chassis 705, a rib 711 protruding to the side of the substrate 707 (the outside) is formed between the rib 11 and the rib 12. The rib 711 has a protrusion height lower than a plurality of ribs 13. The chassis 705 is an example of the “first metal plate” according to the present invention.

Between the rib 711 and the substrate 707, the adhesive layer 720 is arranged, and the center portion of the substrate 707 is curved to the side of the chassis 705 by the adhesive layer 720. Hence, the substrate 707 is pressed onto the rib 11 and the rib 12 of the chassis 705. The adhesive layer 720 is an example of a “first adhesive layer” according to the present invention.

In the eighth embodiment, the adhesive layer 720 is cured with the center portion of the substrate 707 curved to the side of the chassis 705, and thus the curve of the substrate 707 is maintained.

The structure of the other portions in the eighth embodiment is the same as in the sixth and seventh embodiments.

In the eighth embodiment, as described above, the adhesive layer 720 adhering the substrate 707 to the chassis 705 is provided, and thus it is possible to prevent the chassis 705 from separating from the substrate 707, with the result that it is possible to reliably bring the ribs 11 and 12 into contact with the substrate 707 (the heat dissipation sheet 8).

The other effects of the eighth embodiment are the same as those of the sixth and seventh embodiments.

### Ninth Embodiment

In a ninth embodiment, a case where, unlike the first to eight embodiments, an elastic member 820 is provided between a chassis 805 and the substrate 7 will be described with reference to FIGS. 19 and 20.

In the ninth embodiment, as shown in FIG. 19, the chassis 805 includes the ribs 11 and 12 protruding to the side of the substrate 7 (the outside) and a plurality of ribs 813 arranged in the portions of the chassis 805 corresponding to the edge portions 7d (see FIG. 20) of the substrate 7. The chassis 805 is an example of the “first metal plate” according to the present invention; the ribs 813 are an example of a “third protrusion portion” according to the present invention.

Here, in the ninth embodiment, between the ribs 813 and the substrate 7, the elastic members 820 that adjust the distance from the chassis 805 (the ribs 813, 11 and 12) to the substrate 7 are arranged. The elastic member 820 is formed of, for example, silicone rubber, nylon or urethane rubber, and can be elastically deformed. The elastic member 820 is an example of a “first elastic member” according to the present invention.

In the rib 813, as shown in FIG. 20, a screw hole 813a is formed. In the screw hole 811a, a screw thread may be formed.

In the elastic member 820 and the substrate 7, screw holes 820a and 7e are respectively formed in the positions corresponding to the screw hole 813a of the chassis 805.

As shown in FIG. 19, through the screw holes 813a, 820a and 7e (see FIG. 20), a screw 830 is attached, and the screw 830 fixes the substrate 7 to the chassis 805 together with the elastic member 820.

Here, the elastic member 820 is tightened by the screw 830, and thereby is deformed (compressed) into a predetermined thickness.

The structure of the other portions in the ninth embodiment is the same as in the first to eighth embodiments.

In the ninth embodiment, as described above, between the ribs 813 and the substrate 7, the elastic members 820 that adjust the distance from the chassis 805 to the substrate 7 are provided. Thus, it is possible to adjust the distance from the ribs 11 and 12 to the substrate 7, with the result that it is possible to adjust the contact pressure between the ribs 11 and 12 and the substrate 7.

The other effects of the ninth embodiment are the same as those of the first to eighth embodiments.

### Tenth Embodiment

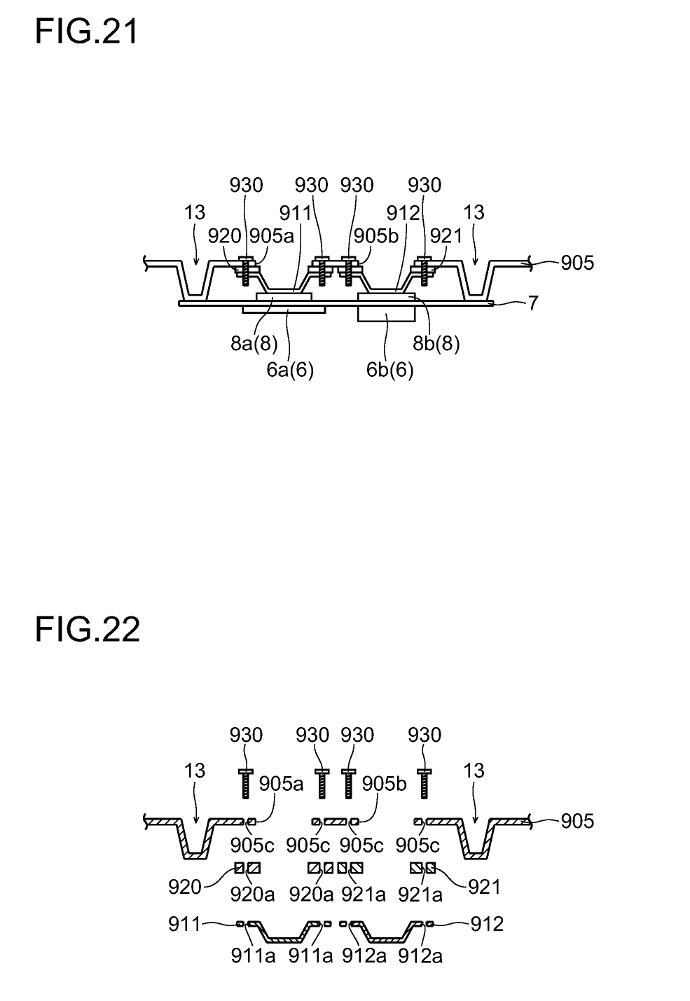

In a tenth embodiment, a case where, unlike the ninth embodiment, protrusion members 911 and 912 are provided in a chassis 905 through elastic members 920 and 921 will be described with reference to FIGS. 21 and 22.

In the tenth embodiment, as shown in FIG. 21, the chassis 905 includes opening portions 905a and 905b that are formed in the vicinity of portions to which a plurality of protrusion members 911 and 912 are attached and a plurality of ribs 13. The chassis 905 is an example of the “first metal plate” according to the present invention; the protrusion members 911 and 912 are an example of the “first protrusion portion” according to the present invention.

As shown in FIG. 22, in the vicinity of the opening portions 905a and 905b of the chassis 905, a plurality of screw holes 905c are formed.

Here, in the tenth embodiment, as shown in FIG. 21, the protrusion members 911 and 912 protruding to the side of the substrate 7 are respectively attached to the chassis 905 so as to block the opening portions 905a and 905b.

Between the protrusion member 911 and the chassis 905, an elastic member 920 for adjusting the distance from the protrusion member 911 to the chassis 905 is arranged. Between the protrusion member 912 and the chassis 905, an elastic member 921 for adjusting the distance from the protrusion member 912 to the chassis 905 is arranged. The elastic members 920 and 921 are formed of, for example, silicone rubber, nylon or urethane rubber, and can be elastically deformed. The elastic members 920 and 921 are an example of a “second elastic member” according to the present invention.

As shown in FIG. 22, in the elastic members 920 and 921 and the protrusion members 911 and 912, screw holes 920a, 921a, 911a and 912a are respectively formed in the positions corresponding to the screw holes 905c of the chassis 905. In the screw holes 911a and 912a, a screw thread may be formed.

As shown in FIG. 21, the screws 930 are attached through the screw holes 905c, 920a, 921a, 911a and 912a (see FIG. 22), and the screws 930 fix the protrusion members 911 and 912 to the chassis 905 together with the elastic members 920 and 921.

Here, the elastic members 920 and 921 are tightened by the screw 930, and thereby are deformed (compressed) into a predetermined thickness.

Although, in FIGS. 21 and 22, the protrusion members 911 and 912 are formed to have a smaller thickness than the chassis 905, the protrusion members 911 and 912 may be formed to have the same thickness as the chassis 905 or may be formed to have a larger thickness than the chassis 905.

In the chassis 905, the opening portions 905a and 905b may not be formed.

The structure of the other portions in the tenth embodiment is the same as in the ninth embodiment.

In the tenth embodiment, as described above, the protrusion members 911 and 912 are respectively attached to the chassis 905 through the elastic members 920 and 921. In this way, it is possible to adjust the distance from the protrusion members 911 and 912 to the chassis 905, and thus it is possible to adjust the distance from the protrusion members 911 and 912 to the substrate 7. Consequently, it is possible to adjust the contact pressure between the protrusion members 911 and 912 and the substrate 7.

The other effects of the tenth embodiment are the same as those of the ninth embodiment.

The embodiments disclosed herein should be considered illustrative in all respects and not restrictive. The scope of the present invention is indicated not by the description of the embodiments discussed above but by the scope of claims, and further includes meanings equivalent to the scope of claims and all modifications within the scope.

For example, although, in the above embodiments, the example where the display device is applied to the liquid crystal display device is described, the present invention is not limited to this example; the present invention may be applied to a display device other than the liquid crystal display device.

Although, in the above embodiments, the example where the electronic device is applied to the display device is described, the present invention is not limited to this example; the present invention can be applied to various electronic devices such as portable devices, household electrical machinery and appliances and solar batteries.

Although, in the above embodiments, the example where the liquid crystal display device is formed with a direct-type backlight device is described, the present invention is not limited to this example; the liquid crystal display device may be formed with a side light-type backlight device.

Although, in the fifth to eighth embodiments, the examples where the pressing members, the screw, the band and the adhesive layer for bringing the semiconductor package into contact with the chassis are provided are described, the present invention is not limited to these examples; a combination of two or more of the pressing members, the screw, the band and the adhesive layer for bringing the semiconductor package into contact with the chassis may be used. At least one of these may be used, and furthermore the spring portion may be provided in the chassis.

Although, in the above embodiments, the example where the heat conductive member is formed with the heat dissipation sheet (heat conductive sheet) having a high thermal conductivity is described, the present invention is not limited to this example; the heat conductive member may be formed with a heat dissipation grease (for example, silicone grease) or the like having a high thermal conductivity.

Although, in the above embodiments, the example where the substrate is fixed with the screw or the like to the chassis is described, the present invention is not limited to this example; the substrate may be fixed with a fixing member other than the screw to the chassis.

For example, although, in the first and second embodiments, the example where the first protrusion portion (the rib, the protrusion portion) is formed on the chassis is described, the present invention is not limited to this example; the protrusion member (the first protrusion portion) may be formed separately from the chassis and may be attached to the chassis. In this case, regardless of the material of the chassis, the protrusion member (the first protrusion portion) can be formed with a material having a satisfactory thermal conductivity such as copper or aluminum.

Although, in the second embodiment, the example where the though hole is formed in the contact portion is described, the present invention is not limited to this example. In another embodiment, the through hole may be formed in the contact portion.

Although, in the sixth to eighth embodiments, the examples where the screw, the band and the adhesive layer are used to bring the substrate (dissipation sheet) into contact with the chassis are described, the present invention is not limited to these example. An adhesive tap is used to pull the substrate (dissipation sheet) to the side of the chassis or the attractive force or the repulsion force of a magnet or the like is utilized to press the substrate (dissipation sheet) to the side of the chassis, and thus the substrate (dissipation sheet) may be brought into contact with the chassis.

For example, although, in the fifth embodiment, the example where the pressing member is provided to press the substrate to the side of the chassis is described, the present invention is not limited to this example. For example, the frame (a frame holding an electronic device) of a television set or the like may be used to press the substrate to the side of the chassis. In this case, since it is not necessary to additionally provide the pressing member, it is possible to reduce the number of components.

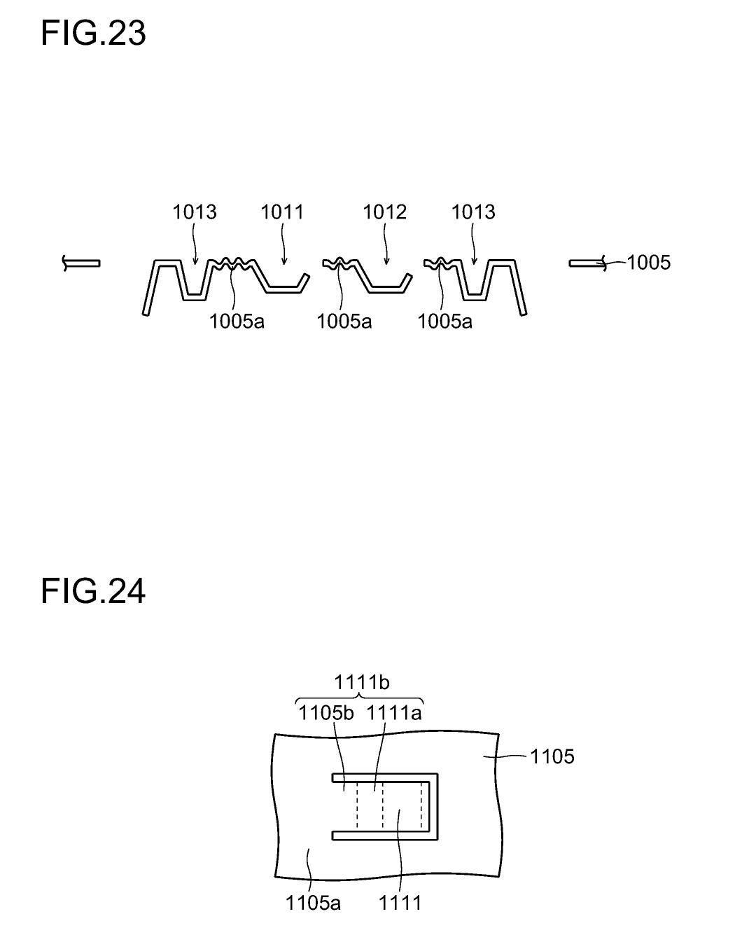

Although, in the above embodiments, the example where the protrusion portions of the chassis and the portions other than the ribs are formed with the flat surface portion is described, the present invention is not limited to this example. As a chassis (the first metal plate) 1005 of a first variation of the present invention shown in FIG. 23, in portions other than protrusion portions (the first protrusion portion, the heat dissipation fin) 1011 and 1012 of a chassis 1005 and ribs (the third protrusion portion) 1013, for example, wavy ribs 1005a may be formed. With this configuration, it is possible to more enhance the heat dissipation. In this case, around the protrusion portions 1011 and 1012 in the chassis 1005, the ribs 1005a are preferably formed.

For example, although, in the second embodiment, the example where the spring portion is provided in the protrusion portion is described, the present invention is not limited to this example. For example, as a chassis (the first metal plate) 1105 of a second variation of the present invention shown in FIG. 24, a spring portion 1111b may be formed with a part 1111a of a protrusion portion (the first protrusion portion, the heat dissipation fin) 1111 and a part 1105b of a flat surface portion 1105a.

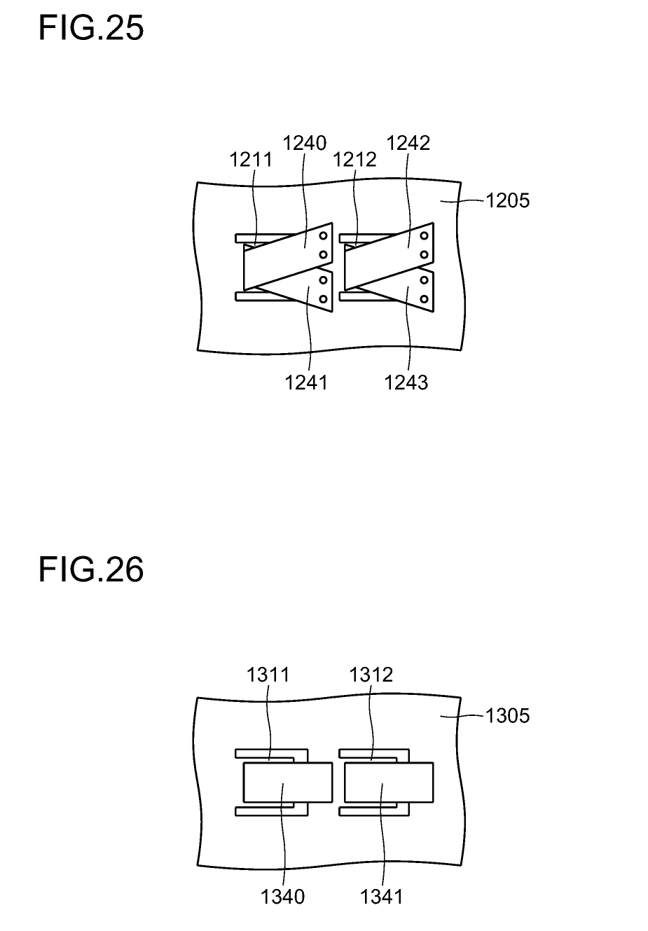

Although, in the third embodiment, the example where the one plate spring is attached to the one protrusion portion is described, the present invention is not limited this example. Two or more plate springs may be attached to the one protrusion portion. For example, preferably, as in a third variation of the present invention shown in FIG. 25, plate springs (the first heat conductive member) 1240 and 1241 are attached to a protrusion portion (the first protrusion portion, the heat dissipation fin) 1211 of a chassis (the first metal plate) 1205, and plate springs (the first heat conductive member) 1242 and 1243 are attached to a protrusion portion (the first protrusion portion, the heat dissipation fin) 1212. In this case, since it is possible to discharge (transmit) the heat generated in the individual semiconductor packages in three directions, it is possible to more enhance the heat dissipation.

Although, in the third embodiment, the example where the plate spring is attached to the protrusion portion is described, the present invention is not limited to this example. A heat conductive member other than the plate spring may be attached. For example, as in a fourth variation of the present invention shown in FIG. 26, metal tapes (the first heat conductive member) 1340 and 1341 such as a copper tape may be attached to protrusion portions (the first protrusion portion, the heat dissipation fin) 1311 and 1312 of a chassis (the first metal plate) 1305.

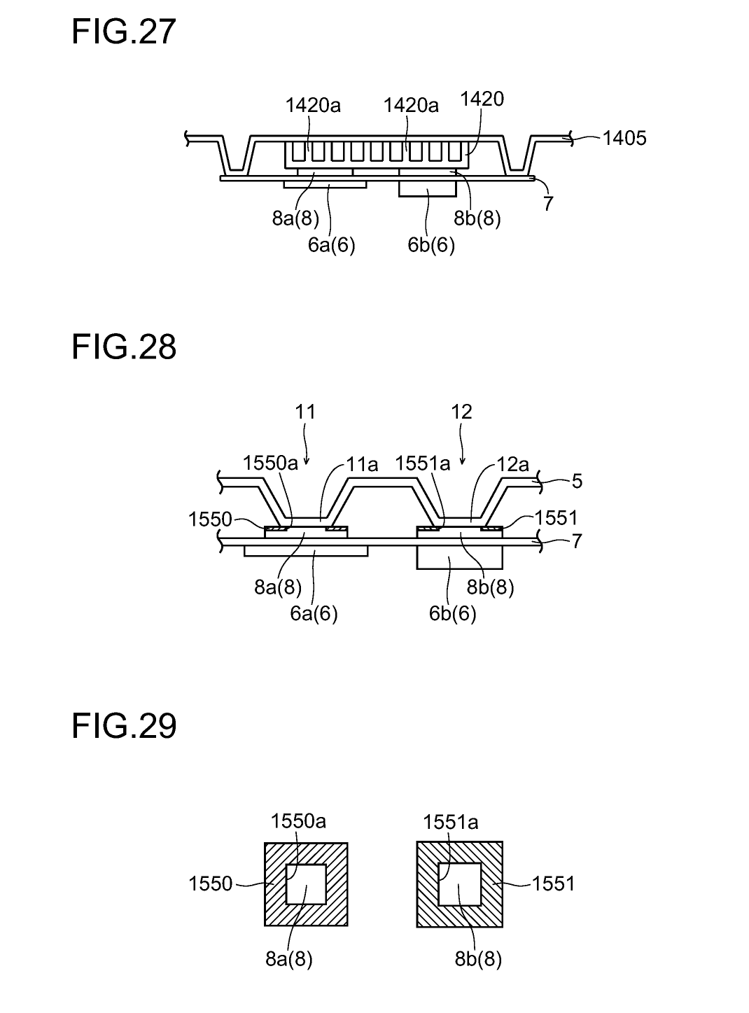

Although, in the above embodiments, the example where the two dissipation sheets are in contact with the two first protrusion portions is described, the present invention is not limited to this example. For example, as in a fifth variation of the present invention shown in FIG. 27, two heat dissipation sheets 8 may be in contact with one heat dissipation fin (the first protrusion portion) 1420 of a chassis (the first metal plate) 1405. A plurality of heat dissipation parts 1420a may be provided in the heat dissipation fin 1420.

Although, in the above embodiments, the example where the two heat dissipation sheets are provided according to the two semiconductor packages is described, the present invention is not limited to this example. One heat dissipation sheet corresponding to the two semiconductor packages may be provided.

Although, in the above embodiments, the example where the first heat conductive member is arranged between the substrate and the first protrusion portion (the rib and the protrusion portion) is described, the present invention is not limited to this example. Between the substrate and the first protrusion portion (the rib, the protrusion portion), the first heat conductive member and the adhesive layer may be arranged. For example, as in a sixth variation of the present invention shown in FIGS. 28 and 29, between the heat dissipation sheet 8 (8a and 8b) and the ribs 11 and 12, adhesive layers (the second adhesive layer) 1550 and 1551 may be arranged. In this configuration, since it is possible to satisfactorily maintain the contact between the heat dissipation sheet 8 (8a and 8b) and the ribs 11 and 12, it is possible to more easily transmit (dissipate) the heat generated in the semiconductor packages 6 (6a and 6b) to the ribs 11 and 12. Thus, it is possible to more enhance the heat dissipation of the liquid crystal display device. As shown in FIG. 29, opening portions 1550a and 1551a may be respectively formed in the center portions of adhesive layers 1550 and 1551, and the adhesive layers 1550 and 1551 may be arranged in only the vicinity of the heat dissipation sheet 8 (8a and 8b). The opening portions 1550a and 1551a may not be formed in the adhesive layers 1550 and 1551, and the adhesive layers 1550 and 1551 may be arranged on the entire surface of the heat dissipation sheet 8 (8a and 8b). The adhesive layers 1550 and 1551 can be easily formed by, for example, applying the adhesive to the heat dissipation sheet 8 (8a and 8b) or adhering a double-sided tape thereto.

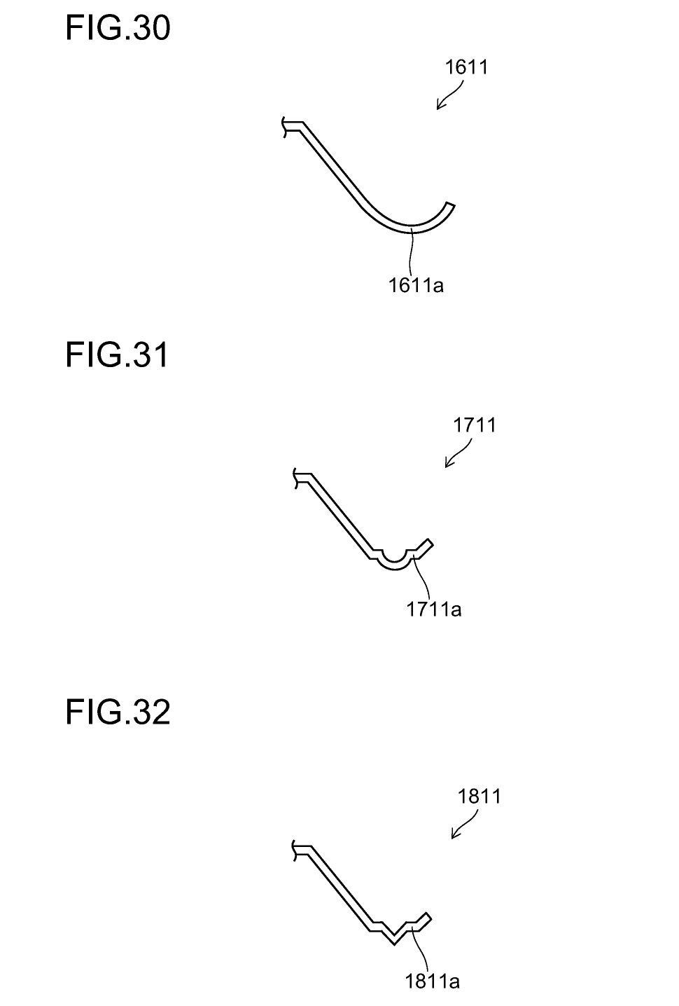

Although, in the above embodiments, the example where the contact portion of the first protrusion portion (the rib, the protrusion portion) is formed into a flat shape is described, the present invention is not limited to this example. The contact portion of the first protrusion portion can be formed in various shapes. For example, as in a seventh variation of the present invention shown in FIG. 30, a contact portion 1611a of a protrusion portion (the first protrusion portion, the heat dissipation fin) 1611 may be curved so as to protrude to the side of the heat dissipation sheet (the side of the substrate). In this case, the contact portion 1611a may be formed to be wavy or semicircular. As in an eighth variation of the present invention shown in FIG. 31, only a part of a contact portion 1711a of a protrusion portion (the first protrusion portion, the heat dissipation fin) 1711 may be curved. As in a ninth variation of the present invention shown in FIG. 32, a contact portion 1811a of a protrusion portion (the first protrusion portion, the heat dissipation fin) 1811 may be formed in the shape of a mountain (triangular pyramid). In the configurations described above, the contact portion of the first protrusion portion can be brought into line contact or point contact with a desired position (for example, a high temperature portion) of the substrate, and thus it is possible to more enhance the heat dissipation of the electronic device. It is also possible to adjust the contact pressure between the contact portion and the substrate.

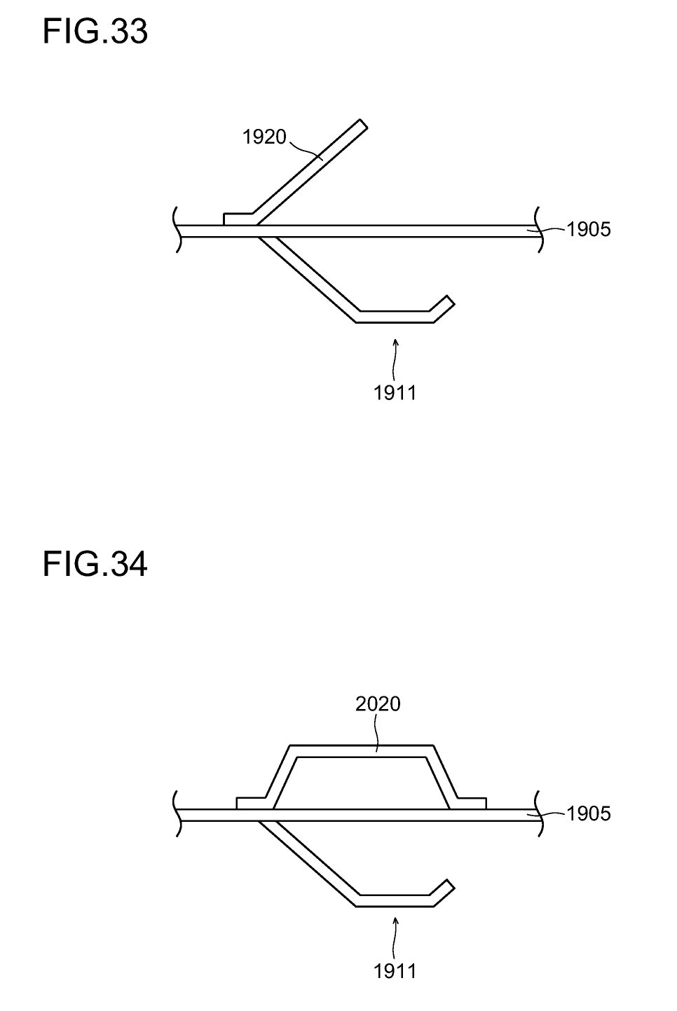

For example, although, in the second embodiment, the example where the heat dissipation fin is provided in the position away from the protrusion portion is described, the present invention is not limited to this example. For example, as in a tenth variation of the present invention shown in FIG. 33, a heat dissipation fin 1920 may be attached to the vicinity of a protrusion portion (the first protrusion portion, the heat dissipation fin) 1911 of a chassis (the first metal plate) 1905. In this case, the heat dissipation fin 1920 is preferably attached to the vicinity of the base portion of the protrusion portion 1911 in the chassis 1905. For example, as in an eleventh variation of the present invention shown in FIG. 34, a box-shaped (rib-shaped) heat dissipation plate 2020 may be attached to the vicinity of the protrusion portion 1911 of the chassis 1905. Although, in the tenth and eleventh variations of the present invention, the example where a part of the chassis is cut out and bent to form the protrusion portion and the heat dissipation fin or the heat dissipation plate is attached to the chassis is described, a part of the chassis may form a heat dissipation fin or a heat dissipation rib and the protrusion portion may be attached to the chassis.

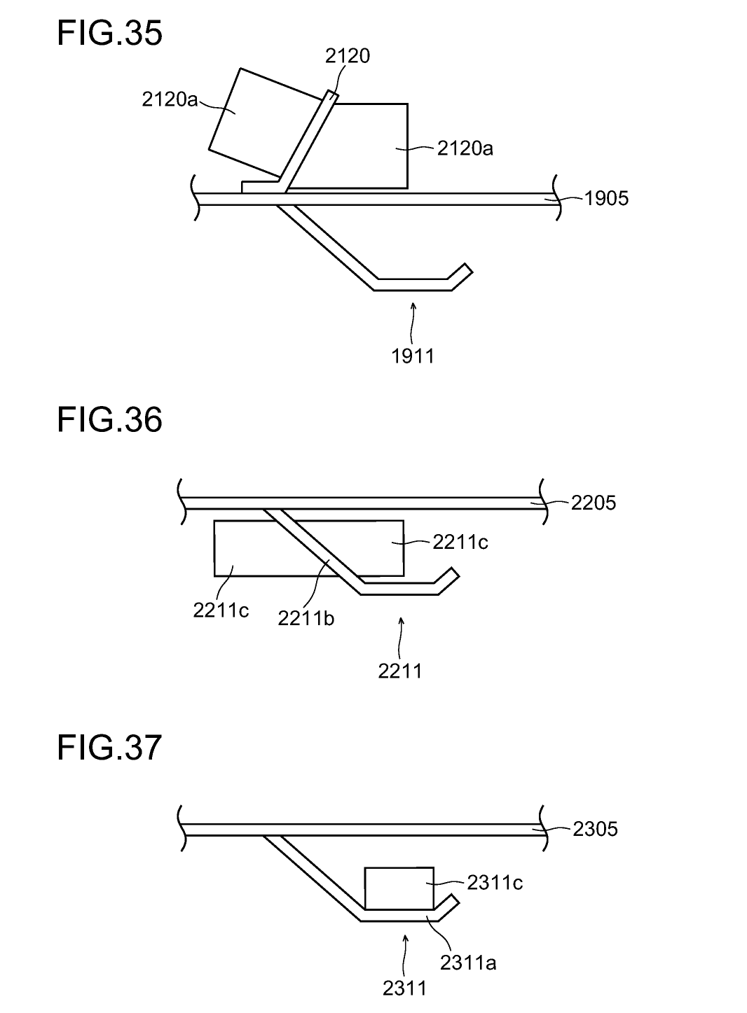

A heat dissipation part may be provided in the heat dissipation fin. Specifically, as in a twelfth variation of the present invention shown in FIG. 35, a heat dissipation part 2120a may be provided in a heat dissipation fin 2120. As in a thirteenth variation of the present invention shown in FIG. 36, a heat dissipation part 2211c may be provided in, for example, a spring portion 2211b of a protrusion portion (the first protrusion portion, the heat dissipation fin) 2211 of a chassis (the first metal plate) 2205; as in a fourteenth variation of the present invention shown in FIG. 37, a heat dissipation part 2311c may be provided in, for example, a contact portion 2311a of a protrusion portion (the first protrusion portion, the heat dissipation fin) 2311 of a chassis (the first metal plate) 2305. A part of the heat dissipation fin may be bent to form these heat dissipation parts or the heat dissipation part may be attached to the heat dissipation fin.

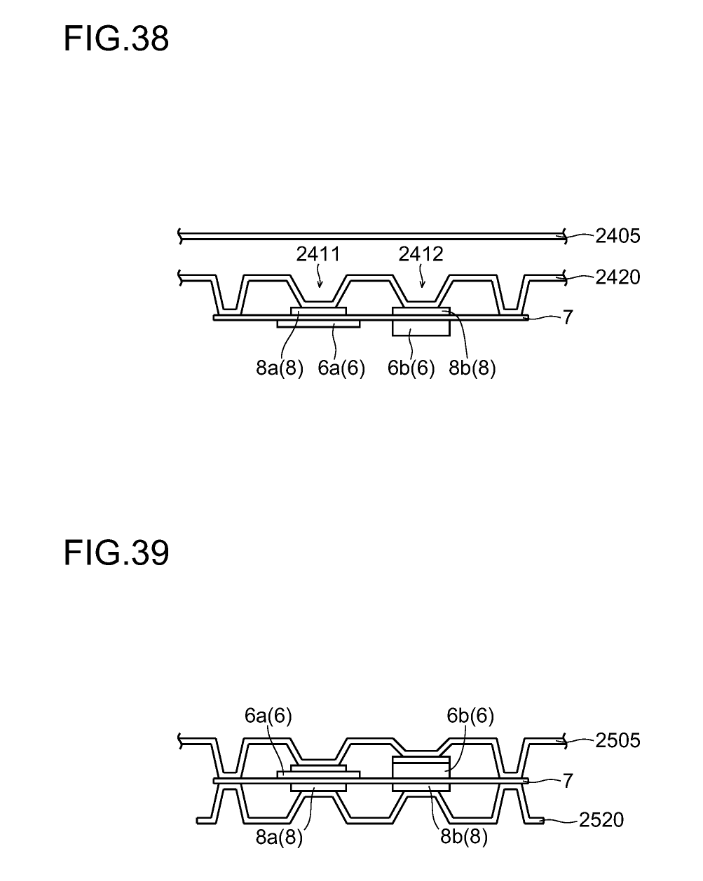

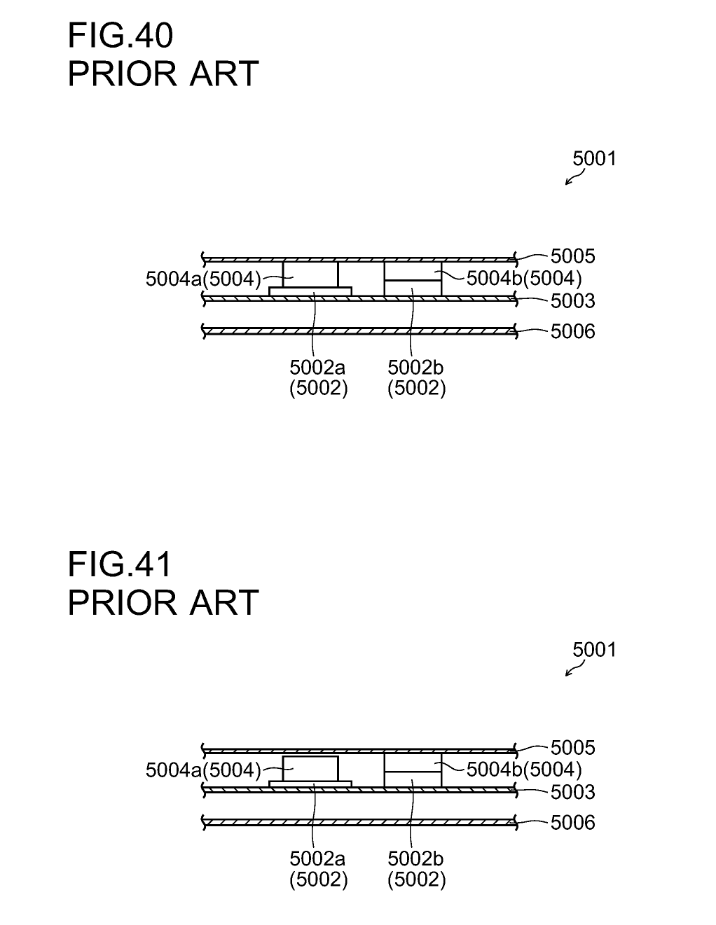

Although, in the above embodiments, the example where the first protrusion portion (the rib, the protrusion portion) is formed in the chassis, and the heat generated in the semiconductor packages is dissipated to the chassis is described, the present invention is not limited to this example. As in a fifteenth variation of the present invention shown in FIG. 38, a metal plate (the first metal plate) 2420 is provided outside a chassis 2405, the heat dissipation sheet 8 is brought into contact with ribs (the first protrusion portion) 2411 and 2412 of the metal plate 2420, and thus the heat generated in the semiconductor packages 6 may be dissipated to the metal plate 2420. The metal plate 2420 is attached with an unillustrated screw or the like to the chassis 2405.

Although, in the above embodiments, the example where the surface on the opposite side to the attachment surface of the substrate is attached to the chassis is described, the present invention is not limited to this example. As a sixteenth variation of the present invention shown in FIG. 39, the attachment surface of the substrate 7 may be attached to the chassis (the second metal plate) 2505. In this case, the metal plate (the first metal plate) 2520 may be provided on the opposite side (the outside) to the chassis 2505 with respect to the substrate 7.

### LIST OF REFERENCE SYMBOLS

1: liquid crystal display device (electronic device, display device)
5, 105, 205, 305, 505, 605, 705, 805, 905, 1005, 1205, 1305, 1405, 1905, 2205, 2305: chassis (first metal plate)
6, 6a, 6b: semiconductor package
7, 507, 607, 707: substrate
7d, 507d: edge portion
8, 8a, 8b: heat dissipation sheet (first heat conductive member)
11, 12, 311, 2411, 2412: rib (first protrusion portion)
13, 813, 1013: rib (third protrusion portion)
105b, 105c, 205b, 205c: cut portion
111, 112, 211, 212, 1011, 1012, 1111, 1211, 1212, 1311, 1312, 1611, 1711, 1811, 1911, 2211, 2311: protrusion portion (first protrusion portion, heat dissipation fin)
111a, 112a, 211a, 212a, 1611a, 1711a, 1811a, 2111a: contact portion
111b, 112b, 211b, 212b, 2211b: spring portion
111c, 112c: through hole
113, 114: fin portion (heat dissipation fin)
205a: flat surface portion (portion of first metal plate other than first protrusion portion)
220, 221, 1240, 1241, 1242, 1243: plate spring (second heat conductive member)
420: pressing member (second metal plate)
431, 432: rib (second protrusion portion)
440, 440a, 440b: heat dissipation sheet (third heat conductive member)
507c, 607c: center portion
520: screw
620: band
720: adhesive layer (first adhesive layer)
820: elastic member (first elastic member)
911, 912: protrusion member (first protrusion portion)
920, 921: elastic member (second elastic member)
1340, 1341: metal tape (second heat conductive member)
1420: heat dissipation fin (first protrusion portion)
1550, 1551: adhesive layer (second adhesive layer)
1920, 2120: heat dissipation fin
2420, 2520: metal plate (first metal plate)
2505: chassis (second metal plate)

1. An electronic device comprising:
a semiconductor package;
a substrate having an attachment surface to which the semiconductor package is attached;
a first metal plate which is arranged opposite a surface on an opposite side to the attachment surface of the substrate and in which a first protrusion portion protruding to a side of the substrate is provided; and
a first heat conductive member which is arranged between the first protrusion portion of the first metal plate and the substrate.

2. The electronic device of claim 1,
wherein the first protrusion portion includes a contact portion which is in contact with the substrate through the first heat conductive member and a spring portion which applies a force acting toward the side of the substrate to the contact portion.

3. The electronic device of claim 2,
wherein the first protrusion portion is formed by bending the first metal plate.

4. The electronic device of claim 2,
wherein a cut portion is formed around the first protrusion portion of the first metal plate.

5. The electronic device of claim 4,
wherein, in the first metal plate, a second heat conductive member is provided which is placed across the cut portion and which is in contact with the first protrusion portion and a portion of the first metal plate other than the first protrusion portion.

6. The electronic device of claim 1, further comprising:
a second metal plate which is arranged on a side of the attachment surface of the substrate; and
a third heat conductive member which is arranged between the second metal plate and the semiconductor package.

7. The electronic device of claim 6,
wherein the second metal plate has a function of pressing the substrate to a side of the first metal plate through the third heat conductive member and the semiconductor package.

8. The electronic device of claim 6,
wherein the second metal plate includes a second protrusion portion which protrudes to a side of the semiconductor package and which is in contact with the third heat conductive member.

9. The electronic device of claim 1,
wherein a plurality of the semiconductor packages and a plurality of the first heat conductive members are provided, and
at least two of the first heat conductive members are formed to have the same thickness and are in contact with the one first protrusion portion.

10. The electronic device of claim 1,
wherein a heat dissipation fin is provided in the first metal plate.

11. The electronic device of claim 10,
wherein the heat dissipation fin is formed by cutting out the first metal plate.

12. The electronic device of claim 1,
wherein the first protrusion portion includes a contact portion which is in contact with the substrate through the first heat dissipation member, and
a through hole is formed in the contact portion.

13. The electronic device of claim 1, further comprising:
at least one of a screw and a band which are attached to the substrate and the first metal plate and which press a center portion of the substrate to the side of the first metal plate.

14. The electronic device of claim 1, further comprising:
a first adhesive layer which adheres the substrate to the first metal plate.

15. The electronic device of claim 1,
wherein a third protrusion portion protruding to the side of the substrate is provided in a position of the first metal plate corresponding to an edge portion of the substrate, and
the edge portion of the substrate is attached to the third protrusion portion of the first metal plate.

16. The electronic device of claim 15,
wherein, between the third protrusion portion and the substrate, a first elastic member for adjusting a distance from the first metal plate to the substrate is provided.

17. The electronic device of claim 1,
wherein the first protrusion portion is attached to the first metal plate through a second elastic member for adjusting a distance from the first protrusion portion to the first metal plate.

18. The electronic device of claim 1,
wherein a second adhesive layer is arranged between the first heat conductive member and the first protrusion portion.

19. A display device comprising the electronic device of claim 1.
